(19) United States
(12) Patent Application Publication
(10) Pub. No.: US 2011/0169990 A1
(43) Pub. Date: Jul. 14, 2011

(54) CURRENT GENERATION CIRCUIT, AND SINGLE-SLOPE ADC AND CAMERA USING THE SAME

(75) Inventors: Masahiro HIGUCHI, Hyogo (JP); Hiroshi Kimura, Osaka (JP)

(73) Assignee: PANASONIC CORPORATION, Osaka (JP)

(21) Appl. No.: 13/050,470

(22) Filed: Mar. 17, 2011

Related U.S. Application Data
(63) Continuation of application No. PCT/JP2009/004069, filed on Aug. 24, 2009.

(30) Foreign Application Priority Data
Sep. 29, 2008 (JP) 2008-251596

(51) Int. Cl. H04N 5/335; H03M 1/00; G05F 1/10

(52) U.S. Cl. 348/302; 341/110; 327/538; 327/543; 348/E05.091

(57) ABSTRACT

A linear relationship is established between a gain control signal and an amplification factor (value in dB). Described is a current generation circuit including a first current output section which outputs a first current, a second current output section which outputs a second current proportional to the first current, and a variable-current control section which generates a third current proportional to the first current, divides the third current into a fourth current and a fifth current according to a first control signal, and outputs the fourth and the fifth currents. The current generation circuit outputs a sum of the first and the fourth currents as a reference current, and a sum of the second and the fifth currents as an output current.

### CROSS-REFERENCE TO RELATED APPLICATION

This is a continuation of PCT International Application PCT/JP2009/004069 filed on Aug. 24, 2009, which claims priority to Japanese Patent Application No. 2008-251596 filed on Sep. 29, 2008. The disclosures of these applications including the specifications, the drawings, and the claims are hereby incorporated by reference in its entirety.

### BACKGROUND

The technology disclosed in this specification relates to analog-to-digital converters (hereinafter referred to as ADCs), and more particularly to gain control technology of single-slope ADCs.

In recent years, image sensors having a large number of pixels have been used in digital camera systems. In order to achieve high speed video imaging, image sensors include ADCs corresponding to respective columns of a pixel array, and perform analog-to-digital conversion of output signals from a line of pixels during a horizontal scan period. Such analog-to-digital conversion is called “column parallel analog-to-digital conversion.” A single-slope ADC having a relatively small circuit size is often used as an ADC for column parallel analog-to-digital conversion due to limited mounting area.

A single-slope ADC inputs a reference ramp signal correlated to a count value of a counter to a comparator as a reference voltage, compares an analog signal to be converted with the reference ramp signal, holds the count value when the both signal values match, and outputs this count value as a result of analog-to-digital conversion. In order to maximally utilize the performance of an ADC and to prevent the signal-to-noise ratio (SNR) from lowering due to quantization noise etc., processing of pixel signals in an image sensor generally requires, upstream of the ADC, analog gain control to amplify the pixel signals to be converted to a suitable level for the dynamic range of the ADC. In a single-slope ADC, analog gain control is achieved by changing the resolution of the ADC by changing the maximum voltage of the reference ramp signal, thus by controlling the slope of the reference ramp signal, depending on a gain control signal, which is a digital value provided from the outside world.

As resolutions of ADCs have been increased, analog gain control with higher accuracy has been required. In addition, increase of the dynamic ranges of pixel signals has required a broader gain control range. Moreover, in order that the amplification factor (value in dB) of an ADC may be linear with respect to the value of a gain control signal, the amplitude of the reference ramp signal is generally changed exponentially with respect to the value of the gain control signal. As technologies to provide such gain control, the following techniques are known.

Patent Document 1 describes a technology to supply a variable reference voltage from a reference voltage generation circuit to a voltage-summing digital-to-analog converter (hereinafter referred to as DAC) which outputs a reference ramp signal. A voltage divided by a resistor chain, in which a plurality of resistors are connected in series, is selected according to a digital control signal, and supplied as the maximum voltage of the ramp signal. A nonlinear weighting, which approximates an exponential characteristic, is applied to each unit resistor in the resistor chain.

Patent Document 2 describes a technology to supply a reference current from a current-summing DAC to another current-summing DAC which outputs a reference ramp signal. This technology allows the slope of the ramp signal to be changed with high accuracy according to a digital control signal.

Patent Document 1: Japanese Patent Publication No. 2003-289251

Patent Document 2: Japanese Patent Publication No. 2007-059991

### SUMMARY

However, the technology of Patent Document 1 requires as many voltage division points as the number of levels which can be represented by the value of a control signal. Since the unit resistors of the resistor chain are weighted, increasing the resolution of gain control causes the area occupied by the resistors to be significantly increased. In addition, a decode circuit to generate a control signal for selecting a divided voltage and a selection switch are also required. Therefore, if the ADC is installed, for example, in an image sensor, then increasing the resolution causes an increase of the area of peripheral circuits of the pixel array and an increase of the chip size. Moreover, enough current for driving loads, such as the input capacitance of an output buffer and the resistance of a selection switch, needs to flow through the resistor chain. Thus, in order to increase the resolution, not only extension of the resistor chain but also reduction in the resistance value of each unit resistor are required. However, achievable resolution is limited due to the minimum resistance value of a resistor device allowable in the semiconductor process.

The technology of Patent Document 2 controls the amplitude of the reference ramp signal by a current-summing DAC; therefore, high-accuracy gain control depending on the resolution of the DAC is readily provided, and the circuit area increases by only a small amount. However, in order to control the amplification factor to linearly change with the value of the control signal, the control signal needs to be provided to the DAC as an input after having been converted by digital signal processing using an exponential function. This requires a logic circuit and/or a conversion table for that purpose in a digital circuit section, thus increasing the resolution of gain control results in increases of the size and the area of peripheral circuits of the pixel array. In addition, when the control signal which has been converted using an exponential function is input to the DAC, depending on a given gain range, unselected current cells in the DAC consume power even though these cells do not contribute to operation; thus, such power is wasted.

It is an object of the present invention to provide a current generation circuit by which control is provided so that a linear relationship is established between the gain control signal and the amplification factor (value in dB) in a single-slope ADC while reducing an increase in the circuit area.

A current generation circuit according to an embodiment of the present invention includes a first current output section configured to output a first current, a second current output section configured to output a second current proportional to the first current, and a variable-current control section configured to generate a third current proportional to the first current, to divide the third current into a fourth current and a fifth current according to a first control signal, and to output the fourth and the fifth currents, where the current generation circuit outputs a sum of the first and the fourth currents as a reference current, and a sum of the second and the fifth currents as an output current.

This allows linearity to be established with high accuracy between the first control signal and the logarithm of the output current while reducing an increase in the circuit area. Using this current generation circuit in a single-slope ADC allows high-accuracy control to be provided so that a linear relationship is established between the first control signal and the amplification factor (value in dB).

A single-slope analog-to-digital converter (ADC) according to an embodiment of the present invention includes a current generation circuit, a digital-to-analog converter (DAC) configured to generate a reference ramp signal having a voltage which increases or decreases proportionally to an input count value, and an ADC configured to output the count value. The current generation circuit includes a first current output section configured to output a first current, a second current output section configured to output a second current proportional to the first current, and a variable-current control section configured to generate a third current proportional to the first current, to divide the third current into a fourth current and a fifth current according to a first control signal, and to output the fourth and the fifth currents. The current generation circuit outputs a sum of the first and the fourth currents as a reference current, and a sum of the second and the fifth currents as an output current. A maximum value of the voltage of the reference ramp signal depends on the output current. The ADC counts up according to a clock signal, and outputs as a result of analog-to-digital conversion the count value when the reference ramp signal reaches the voltage of a signal to be converted.

Another single-slope ADC according to an embodiment of the present invention includes a current generation circuit, a DAC configured to generate a reference ramp signal having a voltage which increases or decreases proportionally to an input count value, and an ADC configured to output the count value. The current generation circuit includes a first current output section configured to output a first current, a second current output section configured to output a second current proportional to the first current, a variable-current control section configured to generate a third current proportional to the first current, to divide the third current into a fourth current and a fifth current according to a first control signal, and to output the fourth and the fifth currents, and a load resistor circuit. The current generation circuit outputs a sum of the first and the fourth currents as a reference current, and a sum of the second and the fifth currents as an output current. The load resistor circuit supplies the output current to a reference potential node. A maximum value of the voltage of the reference ramp signal depends on an output voltage generated in the load resistor circuit. The ADC counts up according to a clock signal, and outputs as a result of analog-to-digital conversion the count value when the reference ramp signal reaches the voltage of a signal to be converted.

A camera according to an embodiment of the present invention includes an image sensor configured to convert light which is input to each pixel into a voltage and to output the voltage, and a digital-video-signal processing section configured to perform signal processing on an output of the image sensor. The image sensor includes a pixel array, having a plurality of photodiodes corresponding to the respective pixels, and configured to output an electrical signal depending on detected light, for each column of the plurality of photodiodes, a current generation circuit, a DAC configured to generate a reference ramp signal having a voltage which increases or decreases proportionally to an input count value, and a plurality of column parallel ADCs respectively corresponding to the columns of the plurality of photodiodes. The current generation circuit includes a first current output section configured to output a first current, a second current output section configured to output a second current proportional to the first current, and a variable-current control section configured to generate a third current proportional to the first current, to divide the third current into a fourth current and a fifth current according to a first control signal, and to output the fourth and the fifth currents. The current generation circuit outputs a sum of the first and the fourth currents as a reference current, and a sum of the second and the fifth currents as an output current. A maximum value of the voltage of the reference ramp signal depends on the output current. The plurality of column parallel ADCs each counts up according to a clock signal, and each outputs as a result of analog-to-digital conversion the count value when the reference ramp signal reaches the voltage of a signal output from a corresponding column of the plurality of photodiodes.

According to example embodiments of the present invention, a current generation circuit in which linearity is established with high accuracy between the input gain control signal and the logarithm of the output signal can be easily achieved without using conversion tables, etc. while reducing an increase in the circuit area. In addition, in a single-slope ADC, using an output signal of the current generation circuit as a reference signal providing the amplitude of the reference ramp signal allows high-accuracy gain control while reducing an increase in the circuit size.

### BRIEF DESCRIPTION OF THE DRAWINGS

FIG. 1A is a block diagram illustrating a configuration of a single-slope ADC according to an embodiment of the present invention. FIG. 1B is a block diagram illustrating a configuration of a first variation of the single-slope ADC of FIG. 1A.

FIG. 2 is a graph showing an error resulting from Equation 1.

FIG. 3 is a circuit diagram illustrating an example configuration of the current control circuit of FIGS. 1A and 1B.

FIG. 4A is a circuit diagram illustrating an example configuration of the reference-current control section of FIG. 3. FIG. 4B is a circuit diagram illustrating a configuration of a variation of the reference-current control section of FIG. 4A.

FIG. 5 is a circuit diagram illustrating a configuration of a first variation of the variable-current control section of FIG. 3.

FIG. 6 is a circuit diagram illustrating a configuration of a second variation of the variable-current control section of FIG. 3.

FIG. 7 is a circuit diagram illustrating a configuration of a third variation of the variable-current control section of FIG. 3.

FIG. 8 is a circuit diagram illustrating a configuration of a first variation of the current control circuit of FIG. 3.

FIG. 9 is a circuit diagram illustrating a configuration of a cascode-transistor switch of FIG. 8.

FIG. 10 is a circuit diagram illustrating a configuration of a second variation of the current control circuit of FIG. 3.

FIG. 11 is a circuit diagram illustrating a configuration of a third variation of the current control circuit of FIG. 3.

FIG. 12 is a graph showing an output current characteristic of a current control circuit using the variable-current control section of FIG. 7.

FIG. 13 is a graph showing a gain characteristic of the single-slope ADCs of FIGS. 1A and 1B.

FIG. 14 is a graph showing gain accuracy of the single-slope ADCs of FIGS. 1A and 1B when the current control circuit of FIG. 8 is used.

FIG. 15A is a block diagram illustrating an example configuration of a single-slope ADC having a voltage control circuit. FIG. 15B is a block diagram illustrating a configuration of a variation of the single-slope ADC of FIG. 15A.

FIG. 16 is a circuit diagram illustrating an example configuration of the voltage control circuit of FIGS. 15A and 15B.

FIG. 17 is a circuit diagram illustrating a configuration of a first variation of the voltage control circuit of FIG. 16.

FIG. 18 is a circuit diagram illustrating a configuration of a second variation of the voltage control circuit of FIG. 16.

FIG. 19 is a circuit diagram illustrating a configuration of a third variation of the voltage control circuit of FIG. 16.

FIG. 20 is a circuit diagram illustrating a configuration of a fourth variation of the voltage control circuit of FIG. 16.

FIG. 21 is a graph showing an output voltage characteristic of the voltage control circuit of FIG. 16.

FIG. 22 is a graph showing gain accuracy of the single-slope ADCs of FIGS. 15A and 15B when the voltage control circuit of FIG. 17 is used.

FIG. 23 is a graph showing gain accuracy of the single-slope ADCs of FIGS. 15A and 15B when the voltage control circuit of FIG. 20 is used.

FIG. 24 is a graph showing an output current of the voltage control circuit of FIG. 20.

FIG. 25 is a graph showing an example of an output voltage characteristic of a voltage control circuit.

FIG. 26 is an illustrative diagram of the slope of the reference ramp signal.

FIG. 27 is a block diagram illustrating an example configuration of a camera which uses an image sensor including a single-slope ADC having a variable-gain function.

FIG. 28 is a block diagram illustrating an example configuration of the image sensor of FIG. 27.

FIG. 29 is a circuit diagram illustrating a configuration of a variation of the current control circuit of FIG. 3, in which the output voltage increases as the value of the gain control signal D increases.

FIG. 30 is a circuit diagram illustrating a configuration of a variation of the voltage control circuit of FIG. 18.

### DETAILED DESCRIPTION

Example embodiments of the present invention will be described below with reference to the drawings, in which the last two digits of the reference numerals are repeated to designate the same or similar components which correspond to one another.

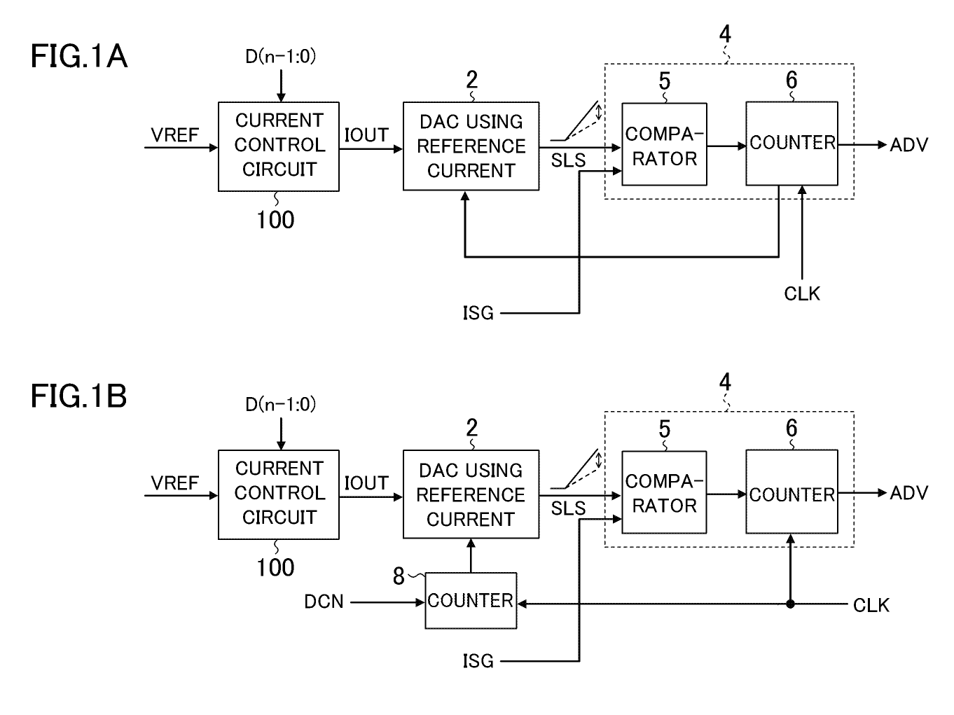

FIG. 1A is a block diagram illustrating an example configuration of a single-slope ADC according to an embodiment of the present invention. The single-slope ADC of FIG. 1A includes a current control circuit 100 as a current generation circuit, a DAC 2 which uses a reference current, and an ADC 4. The ADC 4 includes a comparator 5 and a counter 6.

The current control circuit 100 outputs an output current IOUT having an amount depending on both a reference potential VREF and an n-bit (where n is a natural number) gain control signal D(n−1:0). A gain control signal D(n2:n1) (where n1 and n2 are integers satisfying 0≦n1<n and 0≦n2<n, respectively), as used herein, denotes the bits from n1-th bit to n2-th bit of the gain control signal D, and a gain control signal D(n1) denotes the n1-th bit of the gain control signal D. The zeroth bit is the least significant bit of the gain control signal D.

The DAC 2 generates and outputs a reference ramp signal SLS having a voltage proportional to the count value of the counter 6. The DAC 2 uses the output current IOUT as the reference current, and sets the amplitude (maximum value) of the reference ramp signal SLS to a value depending on the output current IOUT. The description below assumes that the DAC 2 sets the amplitude of the reference ramp signal SLS to a value proportional to the output current IOUT.

The comparator 5 compares a signal to be converted ISG, which is an analog signal, with the reference ramp signal SLS, and notifies the counter 6 when the both match. The counter 6 counts pulses of a clock CLK. The counter 6 holds a count value when a notice is received from the comparator 5, and outputs the count value as an analog-to-digital conversion result ADV. Then, the counter 6 resets the count value. Accordingly, the value of the analog-to-digital conversion result ADV is proportional to the reciprocal of the value of the output current IOUT.

Here, the current control circuit 100 sets the output current IOUT to a value proportional to an exponential function of the gain control signal D so that the output current IOUT decreases as the value of the gain control signal D increases. This causes the logarithm of the analog-to-digital conversion result ADV, which is output from the counter 6, to be linear with respect to the gain control signal D. That is, a linear relationship is established between the gain control signal D and the amplification factor (value in dB) of the single-slope ADC of FIG. 1A. As used herein, the term “linear” refers to a relationship in which, for example, the amplification factor (value in dB) is expressed by a linear expression of the gain control signal D.

FIG. 1B is a block diagram illustrating a configuration of a variation of the single-slope ADC of FIG. 1A. The single-slope ADC of FIG. 1B further includes a counter 8, in addition to the components of the single-slope ADC of FIG. 1A. The counter 8 counts pulses of the clock CLK. The DAC 2 generates and outputs a reference ramp signal SLS having a voltage proportional to a count value of the counter 8, not of the counter 6. Since the counter 8 is controlled by a control signal DCN, various controls can be provided with respect to the reference ramp signal.

Next, a method for changing the current IOUT into a value depending on an exponential function of the gain control signal D will be discussed. The exponential characteristic of the current IOUT with respect to the gain control signal D, which is a digital value, needs to be provided with high accuracy. Since the binary number system is often used in digital control, an exponential function of base 2 is convenient. An almost ideal characteristic can be obtained for integer exponents; however, some approximation needs to be performed for decimal exponents.

Thus, to make the circuits as simple as possible, a high-accuracy exponential approximation is performed using a simple function. For example, an approximation equation yielding a very small error which uses a fractional function such as Equation 1 shown below is known:

2^{x}≈L(x)=(24+10x)/(24−7x) (0≦x≦1) (1)

(See Barbour, J. M., “A geometrical approximation to the roots of numbers,” The American Mathematical Monthly, Vol. 64, No. 1 (January, 1957), pp. 1-9).

Assuming that x is expressed by, for example, a p-bit number “t,” Equation 1 can be rewritten as follows by replacing the continuous variable x with a discrete value t/2^{p}:

2^{x}≈{24+10(t/2^{p})}/{24−7(t/2^{p})} (p is an integer more than 1, and t is an integer satisfying 0≦t≦2^{p}) (2)

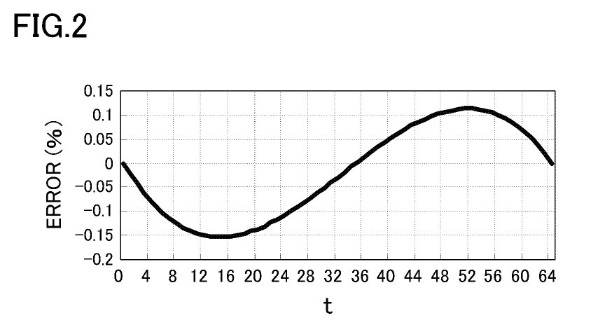

FIG. 2 is a graph showing an error resulting from Equation 1. Here, a case of p=6 (x=t/64) is shown. Equation 1 yields an error less than or equal to 0.15% while the exponent x is in a range from 0 to 1, thus significantly high accuracy is achieved.

Generally, 2^{y} can be produced from composition of two exponential functions:

2^{y}=2^{(m+x)}=(2^{m})·(2^{x}) (y is a real number, and m is an integer) (3)

Thus, control is provided so that 2^{m} is expressed by weighting according to each bit value of the most-significant m bits of the number y, and 2^{x} is expressed by the least-significant p bits (the number t) of the number y as Equation 2. If processing is performed in the circuit so that t is reset to zero and m is incremented by one when t=2^{p}, then a carry operation from the lower circuit to the higher circuit can also be performed, and thus continuity is established.

Next, an optimum configuration with respect to Equation 2 corresponding to the control by the lower bits will be discussed. Considering that when the number t increases, the second term in the numerator increases and the second term in the denominator decreases, a circuit corresponding to these terms can be easily achieved by a configuration in which, for example, current routes are switched according to the number t, and such configuration can effectively utilize electric power and the circuit. By multiplying the numerator by 7/2 and the denominator by 5 to match the coefficients in the terms including the number t in the numerator and the denominator of Equation 2, and then by transforming Equation 2, considering that both the second term in the numerator and the second term in the denominator are changed by switching current routes, we obtain:

2^{x}≈(10/7)·{84+35(t/2^{p})}/{85+35(1−t/2^{p})} (p is an integer more than 1, and t is an integer satisfying 0≦t≦2^{p}) (4)

The current corresponding to “35” in Equation 4 is divided into a current corresponding to 35(t/2^{p}) and a current corresponding to 35(1−t/2^{p}) according to the number t, and the former current is added to the current corresponding to “84,” and the latter current is added to the current corresponding to “85.” In this way, the numerator and the denominator of Equation 4 can be expressed. The ratio between the numerator and the denominator allows a high-accuracy approximation of the exponential characteristic by the number t (the least-significant p bits of the number y).

Since the range of the exponent x=t/2^{p} is 0≦x≦1 in Equation 2, the current control circuit 100 can provide the single-slope ADC with a variable amplification function of 0-6 dB. Each current described above is generated based on a reference current which is generated from, for example, a reference potential and a resistor. If the reference current is changed by changing the resistance value of the resistor according to a value of 2^{m}, then the amplification factor of the single-slope ADC can vary more widely.

Although the foregoing description discusses a case where 2^{x} increases from an initial value to a value twice as high (i.e., from 0 dB to −6 dB), a similar argument applies to a case where 2^{x} decreases from an initial value to a half value (i.e., from 0 dB to −6 dB). This case corresponds to the negative sign of the exponent; thus, exchange between the numerator and the denominator in Equation 1 leads to a necessary equation, and a necessary transformation can also be achieved by exchanging the numerator and the denominator in Equation 4.

In the single-slope ADCs of FIGS. 1A and 1B, increase of the slope of the reference ramp signal SLS results in decrease of the analog-to-digital conversion value ADV, and thus the gain decreases; on the contrary, decrease of the slope of the reference ramp signal SLS results in increase of the gain. Accordingly, in this case, an equation obtained by exchanging the numerator and the denominator of Equation 4 is used as the approximation equation.

In this embodiment, a current control circuit and a voltage control circuit based on the principle of the high-accuracy exponential approximation described above will be described more in detail. The single-slope ADCs of FIGS. 1A and 1B are used, for example, as column parallel ADCs for an image sensor. The following describes an example in which n=8 and p=n−2=6.

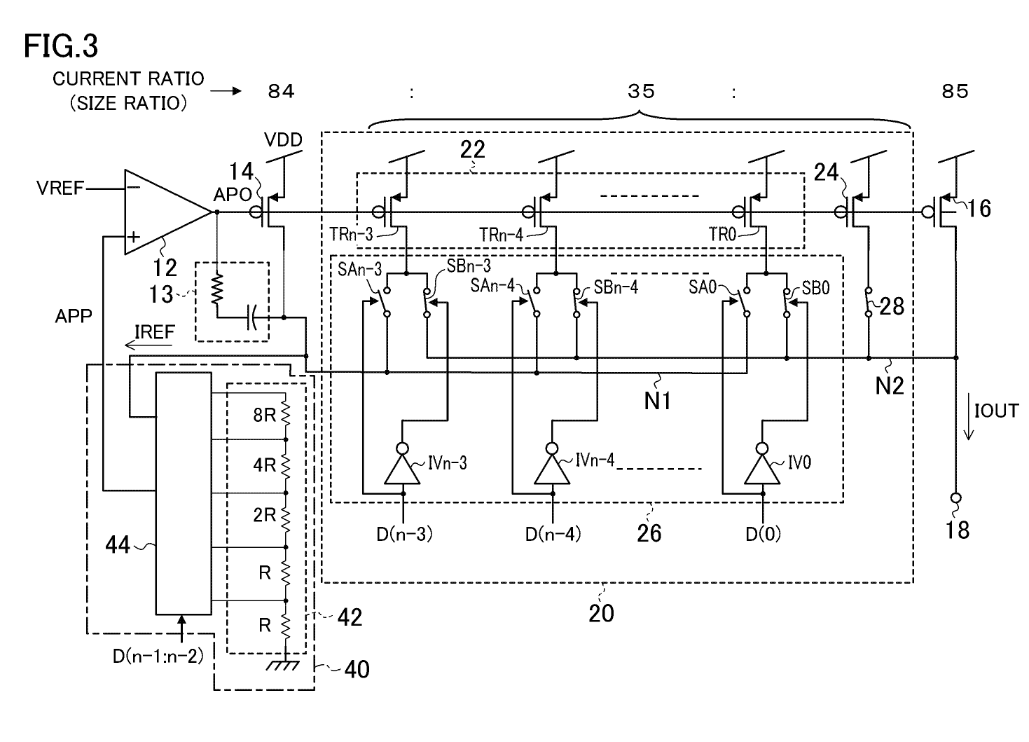

FIG. 3 is a circuit diagram illustrating an example configuration of the current control circuit 100 of FIGS. 1A and 1B. The current control circuit 100 of FIG. 3 includes an operational amplifier 12, a phase compensation circuit 13, a PMOS transistor 14 as a first current output section, a PMOS transistor 16 as a second current output section, a variable-current control section 20, and a reference-current control section 40.

The variable-current control section 20 includes a current source set 22, a PMOS transistor 24 as a unit current source, a current switching section 26, and a switch 28. The current source set 22 includes n−2 PMOS transistors TR0, . . . , TRn−4, and TRn−3 each as a current source. The current switching section 26 includes n−2 inverters IV0, . . . , IVn−4, and IVn−3, and 2(n−2) switches SA0, . . . , SAn−4, SAn−3, SB0, . . . , SBn−4, and SBn−3. The reference-current control section 40 includes a resistor chain (resistor circuit) 42 in which resistors are connected in series, and a selector 44.

The gates of the PMOS transistors 14, 16, and 24, and of the PMOS transistors of the current source set 22 are commonly supplied with an output signal APO of the operational amplifier 12 as a bias signal. Thus, the PMOS transistors 16 and 24, and the current source set 22 respectively output currents proportional to the current of the PMOS transistor 14. The ratio between the current of the PMOS transistor 14 (first current), the current of the PMOS transistor 16 (second current), and the sum of the current of the current source set 22 and the current of the PMOS transistor 24 (third current) is, for example, approximately 84:85:35, and the ratio is almost constant. In this case, the ratio between the size of the PMOS transistor 14, the size of the PMOS transistor 16, and the sum of the sizes of all the PMOS transistors of the current source set 22 and the PMOS transistor 24 is approximately 84:85:35. As used herein, the size of a transistor means, for example, the gate width of a transistor.

The current source set 22 and the PMOS transistor 24 of the variable-current control section 20 generate currents proportional to the current of the PMOS transistor 14, and the variable-current control section 20 divides the generated current into two currents and then outputs the currents. That is, the variable-current control section 20 outputs a part of the current of the current source set 22 to a node N1 according to the least-significant six bits D(n−3:0) (first control signal) of the gain control signal D, and the rest to a node N2. The variable-current control section 20 outputs a current, for example, having a magnitude proportional to the gain control signal D(n−3:0), to the node N1. The sum of the currents output to the node N1 and to the node N2 by the variable-current control section 20 is almost constant.

The current control circuit 100 outputs the sum of the current of the PMOS transistor 14 and the current (fourth current) output from the current source set 22 to the node N1, to the reference-current control section 40, as a reference current IREF. In addition, the current control circuit 100 outputs a current, which is generated by adding the current of the PMOS transistor 16 to the sum (fifth current) of the current output from the current source set 22 to the node N2 and the current of the PMOS transistor 24, from an output terminal 18, as an output current IOUT.

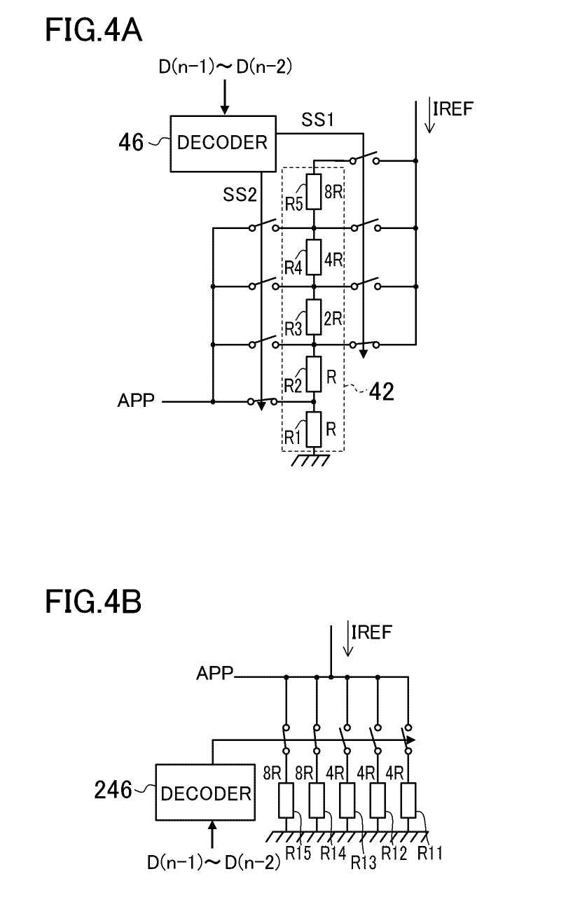

FIG. 4A is a circuit diagram illustrating an example configuration of the reference-current control section 40 of FIG. 3. The reference-current control section 40 includes a decoder 46, resistors R1, R2, R3, R4, and R5, and a plurality of switches. The resistors R1-R5 respectively have resistance values of R, R, 2R, 4R, and 8R (where R is a real number). The decoder 46 and the plurality of switches form the selector 44.

First, a control operation according to the most-significant two bits D(n−1:n−2) (second control signal; here, D(7:6)) of the gain control signal D will be described. The decoder 46 generates two select signals SS1 and SS2 according to the most-significant two bits of the control signal. The tap supplied with the reference current IREF is selected by the select signal SS1, and the tap having a potential of one-half that of the selected tap is selected by the select signal SS2. The voltage of the tap selected by the select signal SS2 is supplied to the non-inverting input of the operational amplifier 12 as an input signal APP.

The operational amplifier 12 provides feedback control for the output voltage APO so that the reference potential VREF supplied to the inverting input and the input signal APP will match. This causes the potential of the node N1 to be stably maintained at twice as high as that of the input signal APP of the operational amplifier 12, and the reference current IREF to be uniquely determined. Note that since the PMOS transistor 14 serves also as a drive transistor of a single-stage amplifier in terms of a feedback loop, the phase compensation circuit 13 is coupled between the gate and the drain of the PMOS transistor 14.

The decoder 46 outputs the select signal SS1 to turn on one switch so that a higher value of the gain control signal D(n−1:n−2) causes the reference current IREF to flow through a resistor having a higher resistance value. Since a smaller slope of the reference ramp signal SLS results in a higher amplification factor in the single-slope ADCs of FIGS. 1A and 1B, the reference current IREF is designed to decrease as the value of the gain control signal D(n−1:n−2) increases.

The resistors R1-R5 are set to have a relationship of powers of two among the values of resistances from the respective voltage-division taps of the resistor chain, formed of the resistors R1-R5, to ground. Therefore, the reference current IREF can be expressed using the maximum value Iref0 of the reference current IREF and the value “s” of the gain control signal D(n−1:n−2) as:

IREF=2^{-s}·Iref0 (s=0, 1, 2, 3) (5)

Next, using as a reference value a current determined in a stepwise fashion by the higher bits of the gain control signal D, a current having a magnitude in a range of values determined by Equation 5 is generated with high accuracy according to the lower bits of the gain control signal D, under the principle expressed by Equation 4. In this regard, since the current should monotonically decrease also with the value of the lower bits, an equation expressing the reciprocal of Equation 4 is used:

2^{-x}≈(7/10)·{85+35(1−t/2^{p})}/{84+35(t/2^{p})} (p is an integer less than or equal to n, and t is an integer satisfying 0≦t−2^{p}) (6)

The current IOUT which is output from the output terminal 18 is expressed as follows.

$$\begin{matrix}IOUT ( t ) = IREF \cdot {2}^{- t} \\ = Iref 0 \cdot ( {2}^{- s} ) \cdot ( {2}^{- t} )\end{matrix}$$

Here, since “7/10” in Equation 6 is a constant, the value 7/10 has no direct effect on the control. Thus, (7/10)·Iref0 is hereinafter rewritten as Iref0. By substituting Equation 6 into the previous equation and then transforming, the previous equation can be rewritten as:

$$\begin{matrix}IOUT ( t ) = IREF \cdot {2}^{- t} \\ = Iref 0 \cdot \frac{\{ 85 + 35 ( 1 - t / {2}^{p} ) \}}{\{ 84 + 35 ( t / {2}^{p} ) \}}\end{matrix} \\ ( \begin{matrix}p is an integer less than or equal to n , \\ and t is an integer satisfying 0 \leq t \leq {2}^{p}\end{matrix} ) \qquad ( 7 )$$

In order to implement the relationship of Equation 7 in a circuit, each current source included in the current source set 22 of the variable-current control section 20 of FIG. 3 outputs a current having a magnitude proportional to the number represented by a corresponding bit of the gain control signal D(n−3:0) (e.g., each of the gate widths of the PMOS transistors TR0-TRn−3 is proportional to the weight of a corresponding bit). More specifically, the ratio between the current values of the respective current sources (PMOS transistors TRn−3-TR0) corresponding to the gain control signals D(n−3), D(n−4), . . . , D(1), and D(0) is set to 2ⁿ⁻³:2ⁿ⁻⁴: . . . :2¹:2⁰.

The inverters IV0, . . . , IVn−4, and IVn−3 respectively output inverted signals of the corresponding gain control signals D(0), . . . , D(n−4), and D(n−3). Each of the switches SA0-SAn−3 and SB0-SBn−3 turns on when the logical value of the control signal thereto is one, and turns off when the logical value is zero. Each of the switches SA0-SAn−3 and SB0-SBn−3 distributes the current of a corresponding current source (hereinafter referred to as “weighted current”) in the current source set 22 into the nodes N1 and N2 according to the gain control signal D(n−3:0).

Thus, the current of each current source in the current source set 22 flows entirely into the node N2 when the gain control signal D(n−3:0) is zero (this corresponds to t=0), and the current distributed to the node N1 is gradually increased every time the gain control signal D(n−3:0) is incremented by one, during which the summed current of the current of the PMOS transistor 14 and the current distributed to the node N1 is maintained at the reference current IREF by the feedback control of the operational amplifier 12. Therefore, the output current IOUT changes while the relationship of the predetermined current ratio (aforementioned 84:85:35) between the current of the PMOS transistor 14, the current of the PMOS transistor 16, and the sum of the currents of the current source set 22 and of the PMOS transistor 24 is maintained.

Eventually, the weighted current entirely flows into the node N1 when the gain control signal D(n−3:0)=2ⁿ⁻²−1 (this corresponds to t=2^{p}−1). In Equation 7, the term {84+35(t/2^{p})} in the denominator corresponds to the summed current of the current of the PMOS transistor 14 and the current distributed to the node N1, and the term {85+35(1−t/2^{p})} in the numerator corresponds to the summed current of the current of the PMOS transistor 16 and the current distributed to the node N2. A current calculated by multiplying the current Iref0 by the ratio between these summed currents is the output current IOUT.

When t=0, Equation 7 is expressed as:

IOUT(0)=Iref0·120/84

and when t=2^{p}, Equation 7 is expressed as:

IOUT(2^{p})=Iref0·85/119

That is, there is a relationship of IOUT(2^{p})=IOUT(0)/2. Here, the current corresponding to “35” of the above current ratio 84:85:35 is expressed by control in the range of the control code 0-2^{p} in Equation 7. However, t=2^{p} is beyond the control range by the gain control signal D(p−1:0) because the gain control signal D(p−1:0) has p bits.

Accordingly, a current of a unit current source (PMOS transistor 24), which supplies the same value of current as that of the current source (PMOS transistor TR0) corresponding to the least significant bit D(0) of the gain control signal D in the current source set 22 of the variable-current control section 20, is always supplied to the node N2. This allows the control of t=2^{p} to be equivalently achieved by a carry operation to the upper bits, and thus the output current IOUT to be monotonically increased. In this way, the variable-current control section 20 exponentially decreases the output current IOUT approximately from an initial value to half the initial value according to the gain control signal D(p−1:0).

In addition, resistors, transistors, etc. (elements in which a current value does not change between the input and the output) may exist on both the output current path of the PMOS transistor 14 and the current path to the node N1 of the variable-current control section 20. The only requirement is that the resistor chain 42 exist between the junction of the both currents and the reference potential (in this embodiment, ground). Similarly, the current of the PMOS transistor 16 and the current to the node N2 of the variable-current control section 20 need to meet, and then be output from the output terminal 18.

As described above, according to the current control circuit 100 of FIG. 3, the output current IOUT can vary in a range from an initial value to one sixteenth thereof using an 8-bit control code when n=8. That is, the logarithm of the output current IOUT can be controlled with high accuracy so as to be proportional to the gain control signal D, in order to allow 256 steps of gain to be set within a variable-gain range of 24 dB.

A switch 28, having a same characteristic as those of the switches SA0 and SB0, corresponding to the least significant bit, in the current source set 22 of the variable-current control section 20, is connected to the PMOS transistor 24. This configuration allows the source-to-drain voltage of the PMOS transistor 24 to be the same as those of the PMOS transistor TR0 etc., thereby reducing a current error due to channel length modulation effects. In particular, if high accuracy of adjustment is required, it is preferable that the resistor value of each switch be inversely proportional to the current flowing therethrough because a weighted current flows through each switch of the current switching section 26 of the variable-current control section 20. Note that, depending on the required accuracy of gain adjustment, such consideration may be omitted.

Although the PMOS transistor 24 is fixedly coupled to the node N2 in the above description, the PMOS transistor 24 may be coupled to the node N1. In this case, the gain setting value shifts only by one stage, thus the accuracy and the variable range of currents are not affected.

FIG. 4B is a circuit diagram illustrating a configuration of a variation of the reference-current control section 40 of FIG. 4A. The reference-current control section of FIG. 4B includes a decoder 246, resistors R11, R12, R13, R14, and R15, and a plurality of switches. The resistors R11-R15 respectively have resistance values of 4R, 4R, 4R, 8R, and 8R. The decoder 246 and the plurality of switches form the selector 44.

The decoder 246 controls each switch according to the gain control signal D(n−1:n−2) so that the combined resistance of the resistor chain will be (a power of two)·R. For example, when the gain control signal D(n−1:n−2)=(1, 1), the decoder 246 turns on only the switch connected to the resistor R15 to set the combined resistance of the resistors to 8R; and when the gain control signal D(n−1:n−2)=(0, 0), the decoder 246 turns on all the switches connected to the resistors R11-R15 to set the combined resistance of the resistors to R. Any configuration may be used as long as the combined resistance of the resistors is set to (a power of two)·R according to the gain control signal D(n−1:n−2).

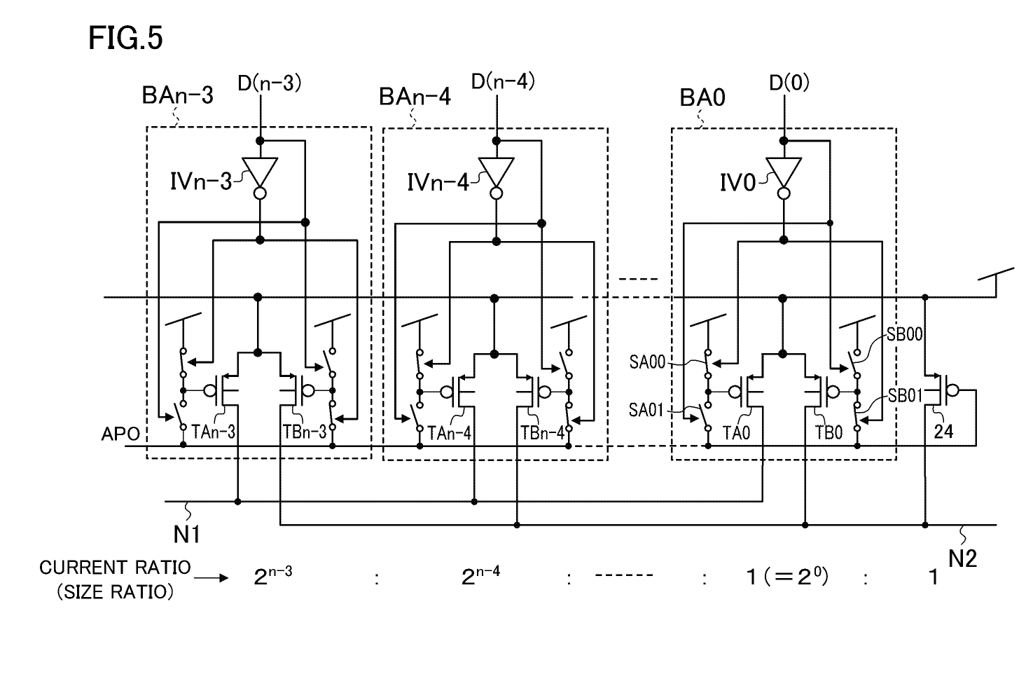

FIG. 5 is a circuit diagram illustrating a configuration of a first variation of the variable-current control section 20 of FIG. 3. The variable-current control section of FIG. 5 includes control circuits BA0, . . . , BAn−4, and BAn−3 corresponding to the respective bits of the gain control signal D(n−3:0), and a PMOS transistor 24 as a unit current source. The sizes of the PMOS transistors TA0 and TB0 of the control circuit BA0 are the same as that of the PMOS transistor TR0 of FIG. 3. Similarly, the sizes of the PMOS transistors TAn−3, TBn−3, etc. of the other control circuits are respectively the same as those of the PMOS transistors of FIG. 3 corresponding to the respective bits of the gain control signal D(n−3:0).

As an example, the control circuit BA0 will be described. The control circuit BA0 includes an inverter IV0, PMOS transistors TA0 and TB0, and switches SA00, SA01, SB00, and SB01. The PMOS transistors TA0 and TB0 are respectively coupled to nodes N1 and N2. The PMOS transistors TA0 and TB0 form a set of current sources, and enable control is provided by the gain control signal D(0).

That is, when the gain control signal D(0)=0, only the switches SA00 and SB01 turn on. The PMOS transistor TA0 turns off and the PMOS transistor TB0 turns on, thus a current flows to the node N2. When the gain control signal D(0)=1, only the switches SA01 and SB00 turn on. The PMOS transistor TB0 turns off and the PMOS transistor TA0 turns on, thus a current flows to the node N1.

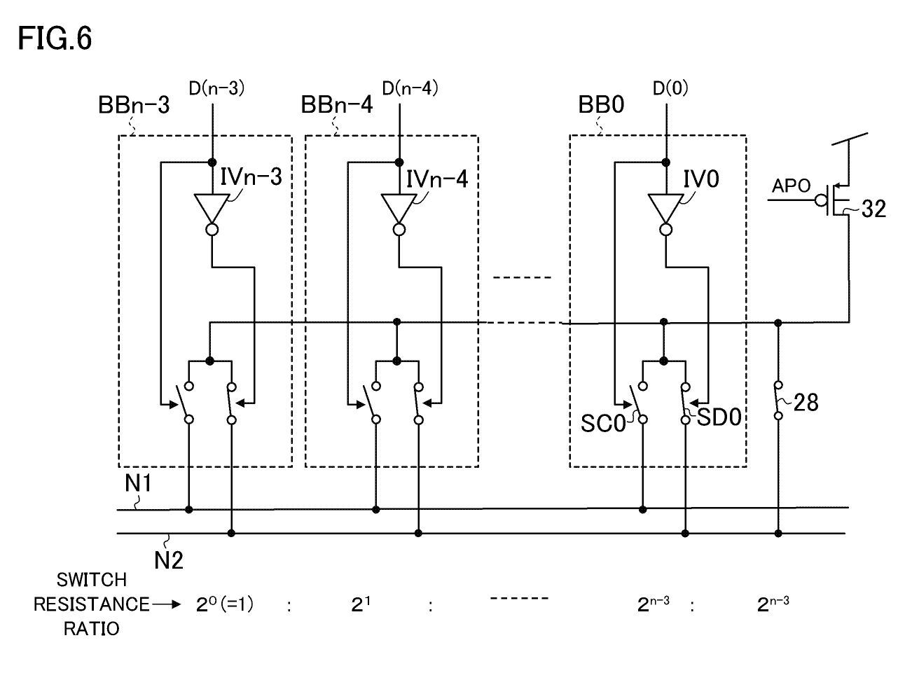

FIG. 6 is a circuit diagram illustrating a configuration of a second variation of the variable-current control section 20 of FIG. 3. The variable-current control section of FIG. 6 includes control circuits BB0, . . . , BBn−4, and BBn−3 corresponding to the respective bits of the gain control signal D(n−3:0), a PMOS transistor 32 as a current source, and a switch 28. The size of the PMOS transistor 32 equals to the sum of all the sizes of the PMOS transistors TR0-TRn−3 and 24 of FIG. 3. That is, the PMOS transistor 32 corresponds to a current source equivalent to the current source set 22 plus the PMOS transistor 24.

The control circuit BB0 includes an inverter IV0, and switches SC0 and SD0. Each of the other control circuits also includes an inverter and two switches. Here, the ratio between the resistances of the switches in the control circuits BB0-BBn−3 is 2ⁿ⁻³:2ⁿ⁻⁴: . . . :2¹:2⁰. The resistance of the switch 28 is the same as that of the switch SC0.

As an example, the control circuit BB0 will be described. When the gain control signal D(0)=0, the switch SD0 turns on, thus a current flows to the node N2. When the gain control signal D(0)=1, the switch SC0 turns on, thus a current flows to the node N1.

In the case of the variable-current control section of FIG. 6, since each switch needs to be supplied with an accurately weighted current, the resistance of each switch needs to be accurately inversely proportional to the current flowing therethrough. In addition, since one end of each switch is connected together, the voltages of the node N1 and the node N2 need to be the same to accurately divide the currents. Thus, a variable-current control section which can relatively easily output currents having accurate values will be described below.

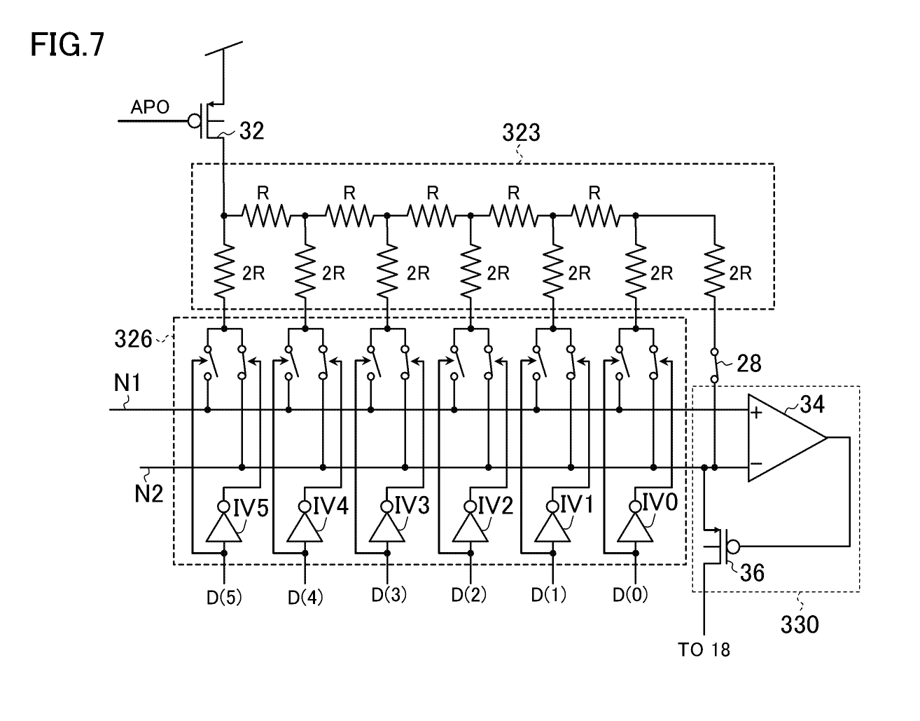

FIG. 7 is a circuit diagram illustrating a configuration of a third variation of the variable-current control section 20 of FIG. 3. The variable-current control section of FIG. 7 includes an R-2R resistor ladder 323, a current switching section 326, a switch 28, a PMOS transistor 32 as a current source, and a bias control circuit 330. The bias control circuit 330 includes an operational amplifier 34 and a PMOS transistor 36. The PMOS transistor 32 is the same as that described in FIG. 6.

The R-2R resistor ladder 323 distributes the current output from the PMOS transistor 32 into weighted currents corresponding to the respective bits of the gain control signal D(n−3:0). The R-2R resistor ladder 323 includes resistors each having a resistance value of R and resistors each having a resistance value of 2R. The terminals not connected to resistors having a resistance value of R, among the terminals of resistors having a resistance value of 2R in the R-2R resistor ladder 323, serve as output terminals of the R-2R resistor ladder 323.

As described above referring to FIG. 3, the node N1 is fixed to a particular bias voltage by the current IREF, determined by higher bits of the gain control signal D, and the resistor chain 42. The non-inverting input of the operational amplifier 34 receives the bias voltage of the node N1, and the inverting input is connected to the node N2. Providing the output of the operational amplifier 34 to the gate of the PMOS transistor 36 causes the operational amplifier 34 and the PMOS transistor 36 to form a negative feedback loop. Thus, the bias control circuit formed of the operational amplifier 34 and the PMOS transistor 36 maintains the bias voltage of the node N1 and the voltage of the node N2 at equal voltages all the time no matter how the higher bits of the gain control signal D are controlled. Note that the resistance value of the resistance chain 42 and the value of the reference current IREF need to be determined so that the bias voltage of the node N1 does not exceed the input range of the operational amplifier 34.

The R-2R resistor ladder 323 can distribute a current with high accuracy by optimizing the layout of the resistors having a resistance value of R and the resistors having a resistance value of 2R so that the ratio between the resistance values is insusceptible to variation in a semiconductor process. In addition, the greater the extent to which the resistance value of each resistor in the resistor ladder 323 exceeds the resistance values of the switches in the current switching section 326 and the switch 28, the smaller the effects on the current accuracy due to variation in the resistance values of the switches can be.

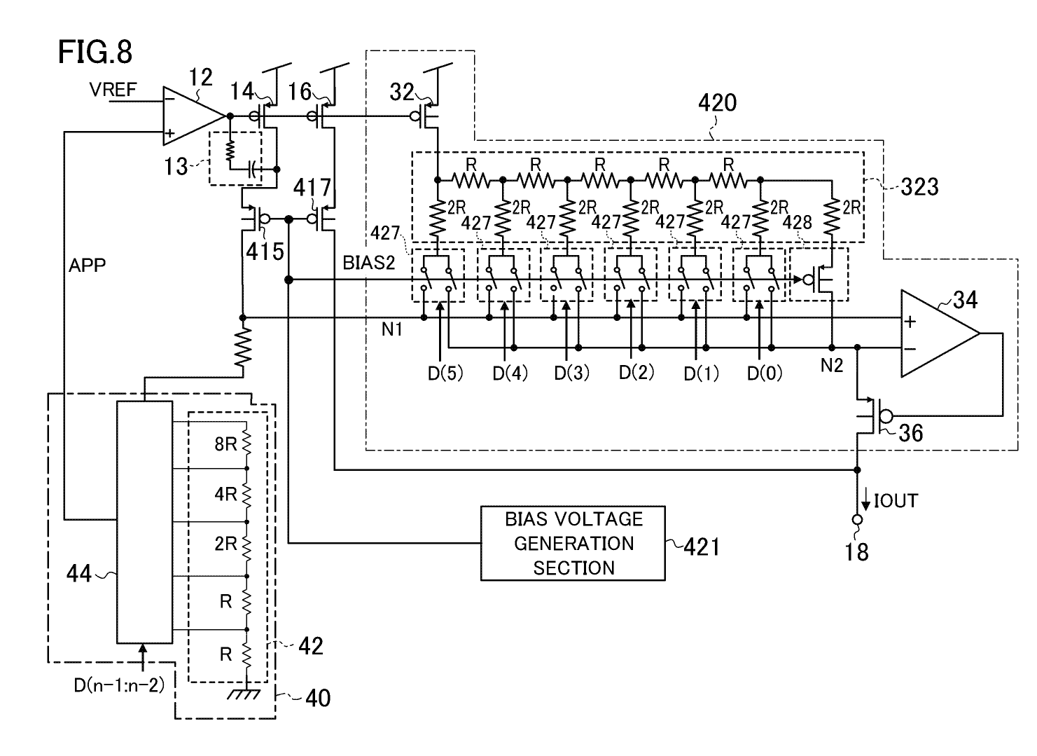

FIG. 8 is a circuit diagram illustrating a configuration of a first variation of the current control circuit of FIG. 3. The current control circuit of FIG. 8 includes a variable-current control section which is partially changed from that of FIG. 7 using an R-2R resistor ladder. The circuit of FIG. 8 includes a variable-current control section 420 instead of the variable-current control section 20, and further includes PMOS transistors 415 and 417 and a bias voltage generation section 421. The variable-current control section 420 includes PMOS transistors 32 and 36, an operational amplifier 34, an R-2R resistor ladder 323, six switches 427, and a unit switch 428.

If the switches of the current switching section 326 of FIG. 7 are used as they are, a difference occurs between the potentials at current output terminals of the resistor ladder 323, thereby causing the accuracy of current division to be reduced. In order to avoid this, cascode-transistor switches 427 are used in the circuit of FIG. 8.

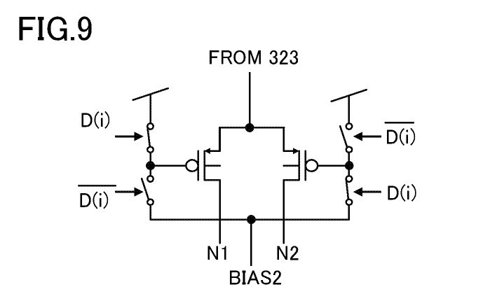

FIG. 9 is a circuit diagram illustrating a configuration of a cascode-transistor switch 427 of FIG. 8. Two PMOS transistors of FIG. 9 function as a switch which allows a current from the resistor ladder 323 to flow to the node N1 or N2. A bias voltage BIAS2 is applied to the gate of one of the two PMOS transistors according to the gain control signal D(i) (where “i” is an integer satisfying 0≦i≦5), and the PMOS transistor to which the bias voltage BIAS2 is applied turns on.

The transistor size of the cascode-transistor switch corresponding to each bit of the gain control signal D(5:0) is proportional to the value of a current which is expected to flow through the transistor. In addition, the transistor size of the cascode-transistor switch 427 corresponding to the least significant bit D(0) of the gain control signal D is the same as that of the unit switch 428. The bias voltage generation section 421 generates and outputs the bias voltage BIAS2. The bias voltage BIAS2 is commonly applied to each of the cascode-transistor switches 427 and to the unit switch 428. Thus, the potentials of the current output terminals of the resistor ladder 323 can be almost the same, thereby preventing the accuracy of current division from being reduced.

Due to a bias effect of the cascode-transistor switches 427, the source-to-drain voltage of the PMOS transistor 32, serving as a current source, becomes lower than the source-to-drain voltages of the PMOS transistors 14 and 16, each serving as a current source, thereby raising the possibility for the linearity of an output voltage to degrade when a higher bit of the gain control signal D changes. Accordingly, the bias transistors 415 and 417 are provided on the current output path of the PMOS transistors 14 and 16, and the bias voltage BIAS2 is applied to the gates thereof in order that the source-to-drain voltages of these current sources may match.

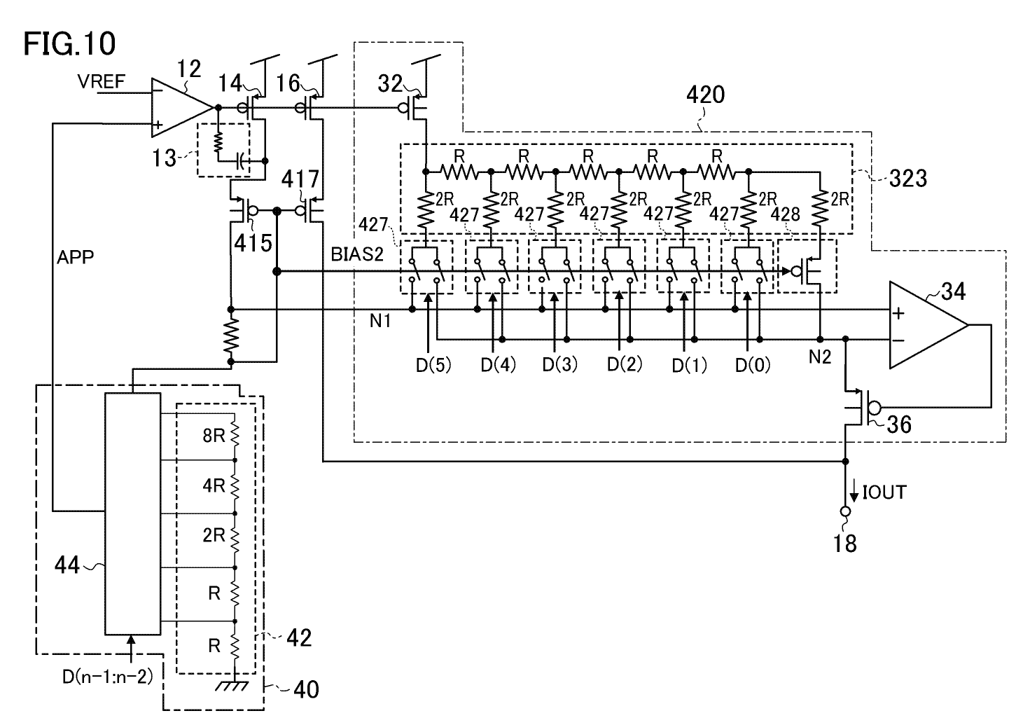

FIG. 10 is a circuit diagram illustrating a configuration of a second variation of the current control circuit of FIG. 3. The current control circuit of FIG. 10 differs from that of FIG. 8 in that the former does not include the bias voltage generation section 421, and that the input voltage to the reference-current control section 40 is the bias voltage BIAS2. The configuration of the circuit of FIG. 10 can simplify the circuit.

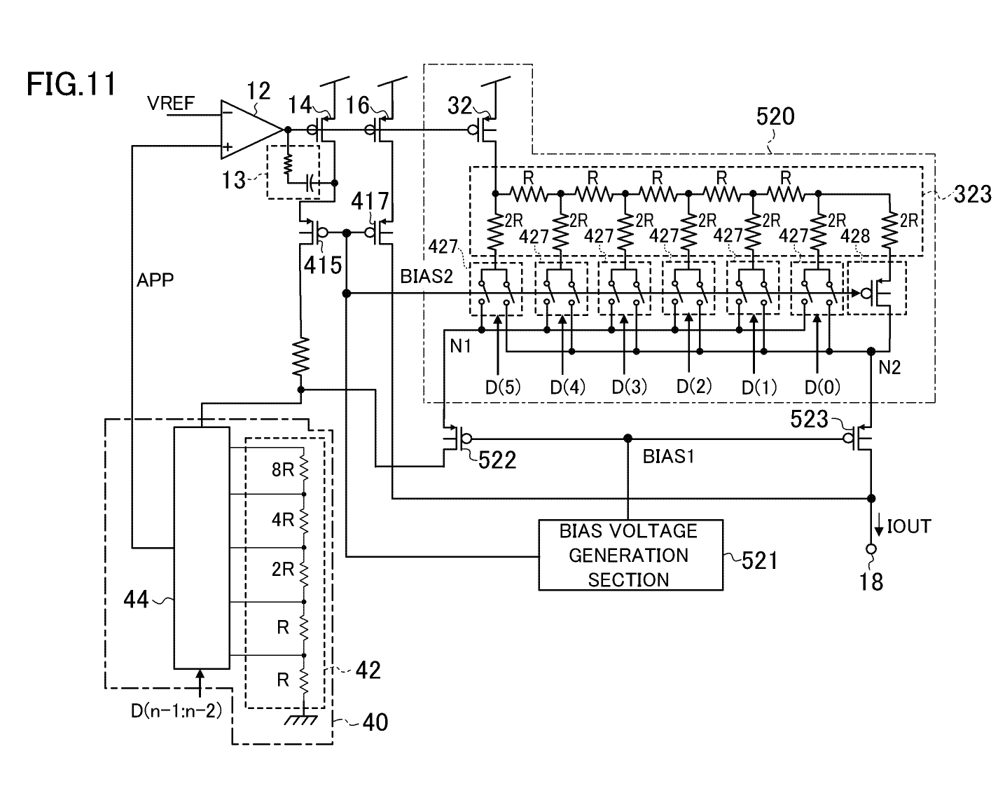

FIG. 11 is a circuit diagram illustrating a configuration of a third variation of the current control circuit of FIG. 3. The current control circuit of FIG. 11 differs from that of FIG. 8 in that the former includes a variable-current control section 520 and a bias voltage generation section 521 instead of the variable-current control section 420 and the bias voltage generation section 421, and further includes PMOS transistors 522 and 523. The variable-current control section 520 differs from the variable-current control section 420 in that the former does not include either the operational amplifier 34 or the PMOS transistor 36.

A current flowed from the resistor ladder 323 to the node N1 flows through the PMOS transistor 522 into the reference-current control section 40. A current flowed from the resistor ladder 323 to the node N2 flows through the PMOS transistor 523, and is output from the output terminal 18. The bias voltage generation section 521 generates and outputs a bias voltage BIAS1 to the gates of the PMOS transistors 522 and 523. The bias voltage generation section 521 generates also the bias voltage BIAS2 similarly to the bias voltage generation section 421.

According to the bias control method of FIG. 8, the entire current control circuit has two operational amplifiers, and their respective feedback loops coexist; this may cause the circuit to be unstable and prone to oscillate depending on circuit parameters. As such, the circuit of FIG. 11 includes the bias transistors 522 and 523 on current output paths passing through the nodes N1 and N2, and applies the common bias voltage BIAS1 to the gates of the both transistors. This prevents, to some extent, the potential difference between the nodes N1 and N2 from expanding, and since the circuit does not include the operational amplifier 34, circuit operations can be stabilized.

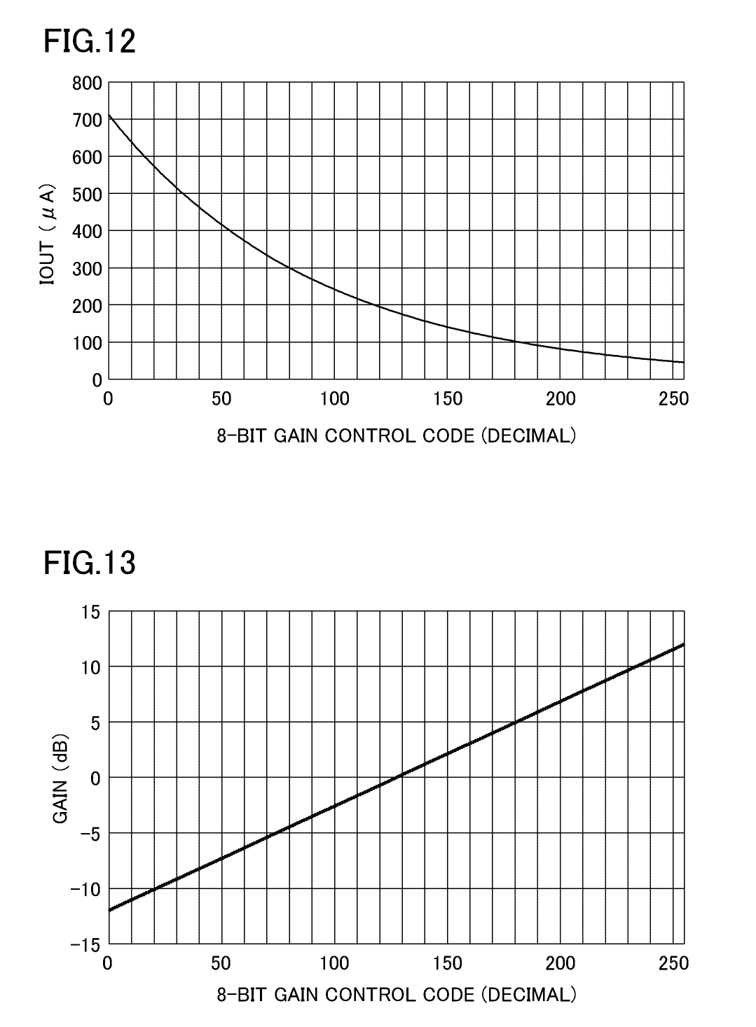

FIG. 12 is a graph showing an output current characteristic of a current control circuit using the variable-current control section of FIG. 7. FIG. 12 shows a relationship between the gain control code, which is the value of the gain control signal D, and the output current IOUT when Iref0≈700 μA and n=8. It is shown that the output current IOUT exponentially decreases with the gain control code.

FIG. 13 is a graph showing a gain characteristic of the single-slope ADCs of FIGS. 1A and 1B. Since the vertical scale is a logarithm, it is shown that the gain (value in dB) linearly increases with the gain control code.

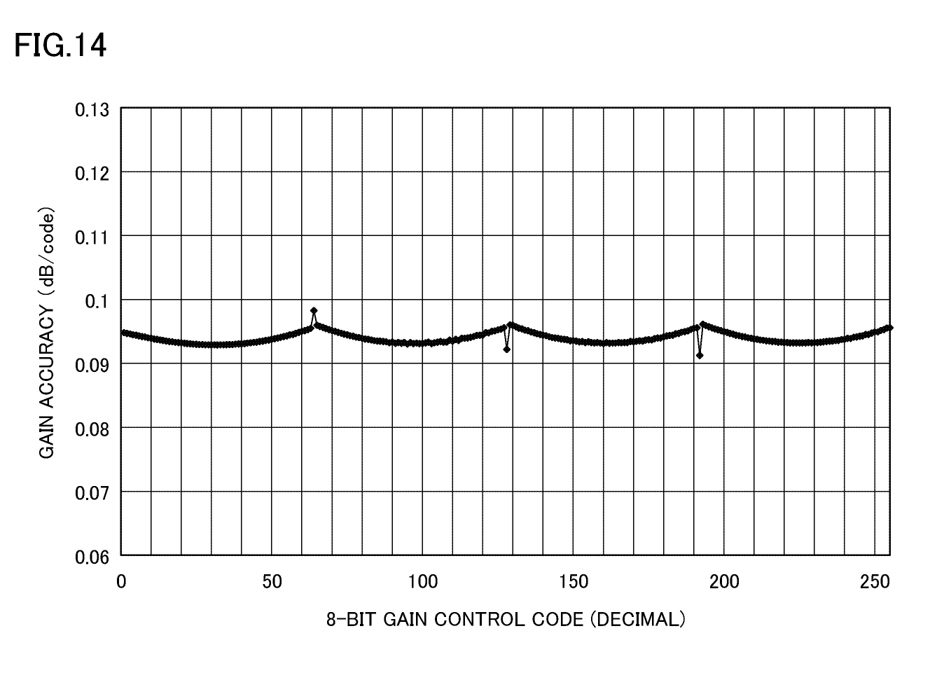

FIG. 14 is a graph showing gain accuracy of the single-slope ADCs of FIGS. 1A and 1B when the current control circuit of FIG. 8 is used. The gain accuracy is maintained at almost a same level within the entire range of the gain control code.

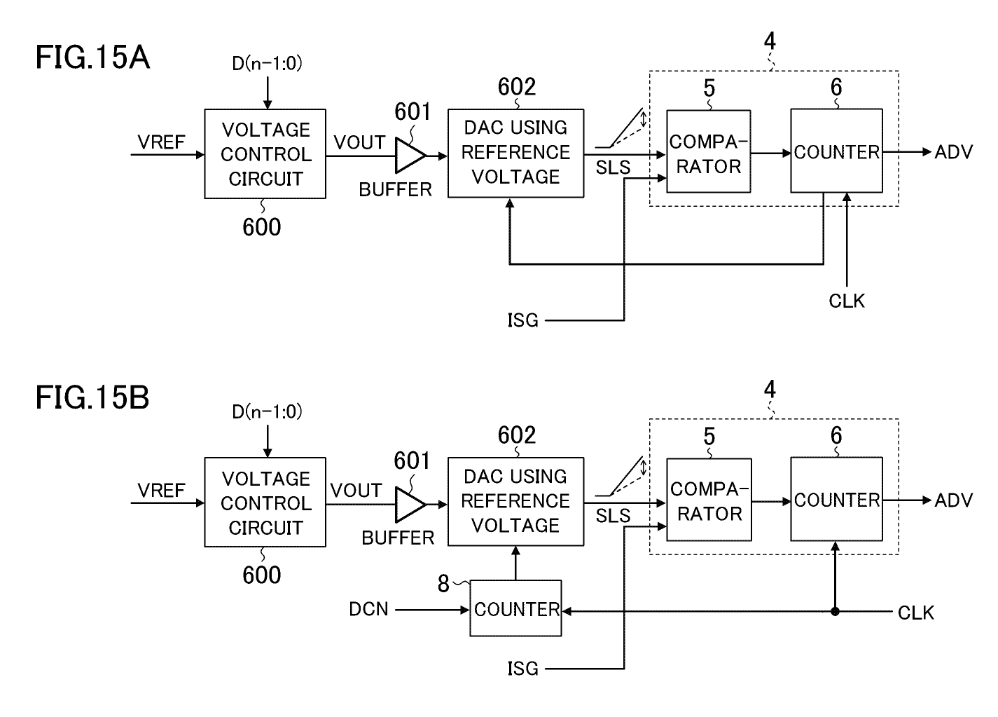

FIG. 15A is a block diagram illustrating an example configuration of a single-slope ADC having a voltage control circuit. The single-slope ADC of FIG. 15A differs from that of FIG. 1A in that the former includes a voltage control circuit 600 as a current generation circuit, and a DAC 602 which uses a reference voltage, instead of the current control circuit 100 and the DAC 2, and further includes a voltage buffer 601.

The voltage control circuit 600 outputs an output voltage VOUT having a magnitude depending on a reference potential VREF and an n-bit gain control signal D(n−1:0). The voltage buffer 601 outputs the output voltage VOUT to the DAC 602 as a reference voltage. Since some level of current-supplying capability is required for applying a reference voltage, the voltage buffer is used. The DAC 602 generates and outputs a reference ramp signal SLS having a voltage proportional to the count value of the counter 6. The DAC 602 uses the output voltage VOUT as the reference voltage, and sets the amplitude (maximum value) of the reference ramp signal SLS to a value depending on the output voltage VOUT. The description below assumes that the DAC 602 sets the amplitude of the reference ramp signal SLS to a value proportional to the output voltage VOUT.

FIG. 15B is a block diagram illustrating a configuration of a variation of the single-slope ADC of FIG. 15A. The single-slope ADC of FIG. 15B further includes a counter 8, in addition to the components of the single-slope ADC of FIG. 15A. The counter 8 counts pulses of a clock CLK. The DAC 602 generates and outputs a reference ramp signal SLS having a voltage proportional to a count value of the counter 8, not of the counter 6. Since the counter 8 is controlled by a control signal DCN, various controls can be provided with respect to the reference ramp signal.

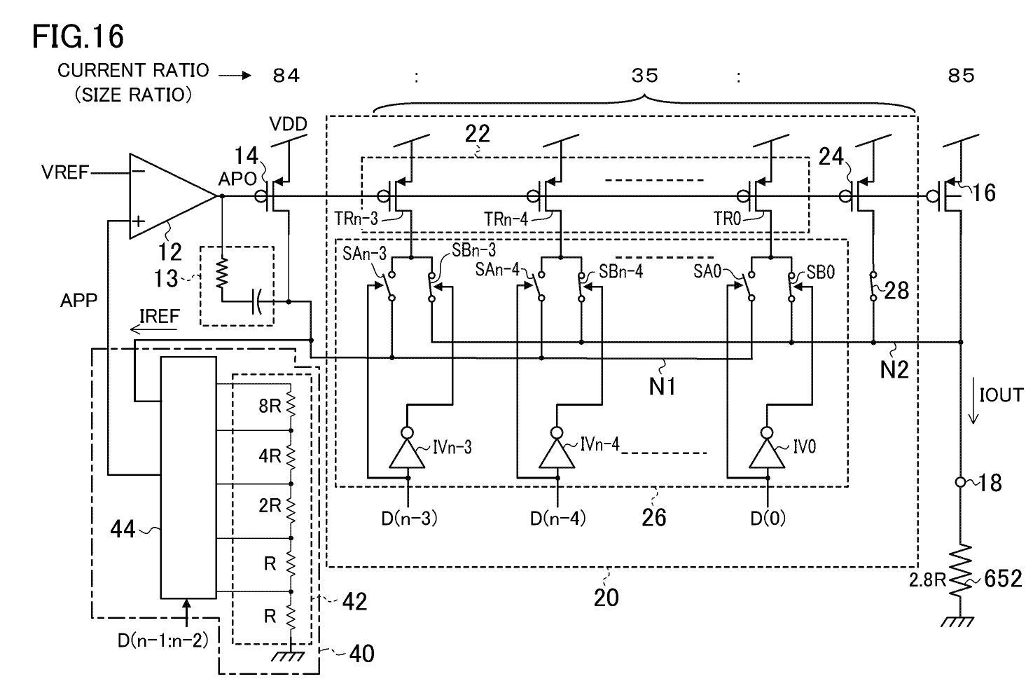

FIG. 16 is a circuit diagram illustrating an example configuration of the voltage control circuit of FIGS. 15A and 15B. The voltage control circuit of FIG. 16 differs from the current control circuit 100 of FIG. 3 in that the former further includes between the output terminal 18 and ground a load resistor 652 (load resistor circuit) which allows the output current to flow to ground. Multiplying the both sides of Equation 7 by the value of the load resistor 652 yields the value of the output voltage VOUT generated across the load resistor 652. As an example, a case will be described where a voltage corresponding to 0 dB is used as the reference potential VREF input to the operational amplifier 12. Let R0 be the resistance between a tap, of the resistor chain 42, selected as the non-inverting input of the operational amplifier 12 when 0 dB is set, and ground, and let Ro be the load resistance. Then, the voltage output VOUT is expressed from Equation 7 as:

VOUT=VREF/R0·{85+35(1−t/2^{p})}/{84+35(t/2^{p})}·Ro (p is an integer less than or equal to n, and t is an integer satisfying 0≦t≦2^{p}) (8)

Assuming that n=8 and the value of the gain control signal D (8-bit control code value) when 0 dB is set is, for example, 80h (hexadecimal), the most-significant two bits of the gain control signal D are (1, 0), and the value of the resistance to ground of the tap, of the resistor chain 42, selected as the non-inverting input of the operational amplifier 12 is 4R in FIG. 16. In addition, the lower bits of the gain control signal D are all zero (i.e., t=0). As such, by substituting these values into Equation 8, we obtain:

$$\begin{matrix}VOUT = VREF / 4 R \cdot 120 / 84 \cdot Ro \\ = VREF\end{matrix} \qquad ( 9 )$$

This is solved for Ro as:

$$\begin{matrix}Ro = 4 \cdot 84 / 120 \cdot R \\ = 2.8 R\end{matrix}$$

Therefore, if the resistance value of the load resistor 652 is 2.8R, the voltage control circuit of FIG. 16 can control the gains of the single-slope ADCs of FIGS. 15A and 15B in 256 steps linearly within a variable voltage range from 4·VREF to 0.25·VREF, that is, from −12 dB to 12 dB in terms of gain.

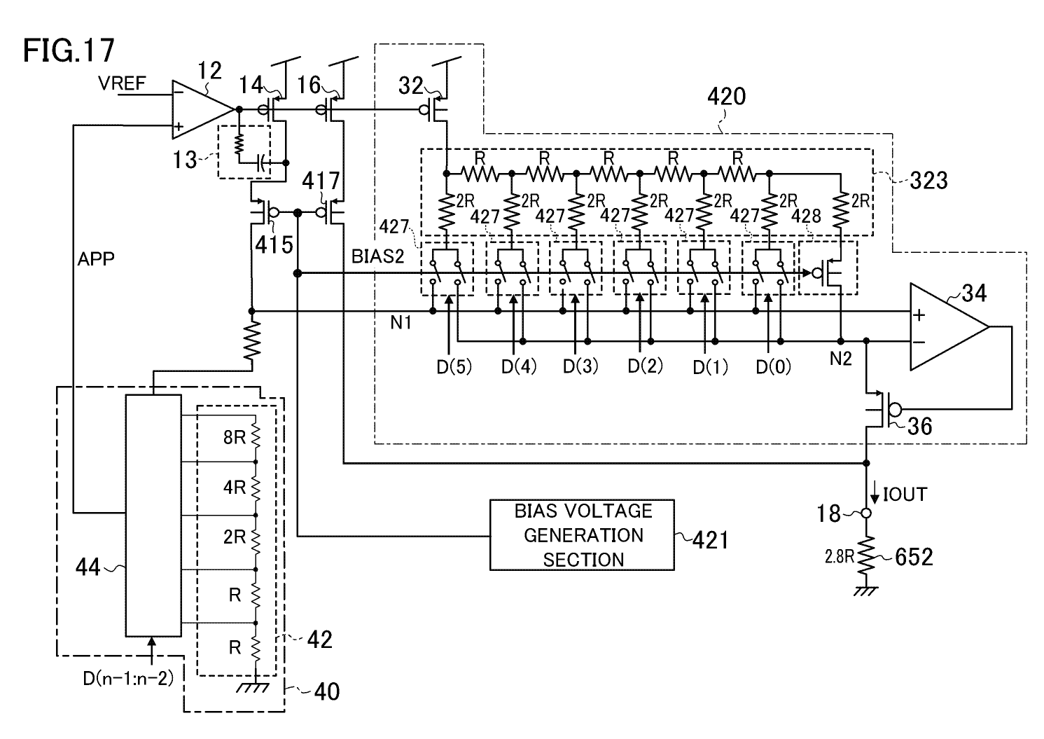

FIG. 17 is a circuit diagram illustrating a configuration of a first variation of the voltage control circuit of FIG. 16. The voltage control circuit of FIG. 17 differs from the current control circuit of FIG. 8 in that the former further includes a load resistor 652 having a resistance value of 2.8R between the output terminal 18 and ground. The other part of configuration is almost the same as the current control circuit of FIG. 8. Since the voltage control circuit of FIG. 17 includes cascode-transistor switches 427, potentials at current output terminals of the resistor ladder 323 can be nearly matched, thereby preventing reduction of the accuracy of current division.

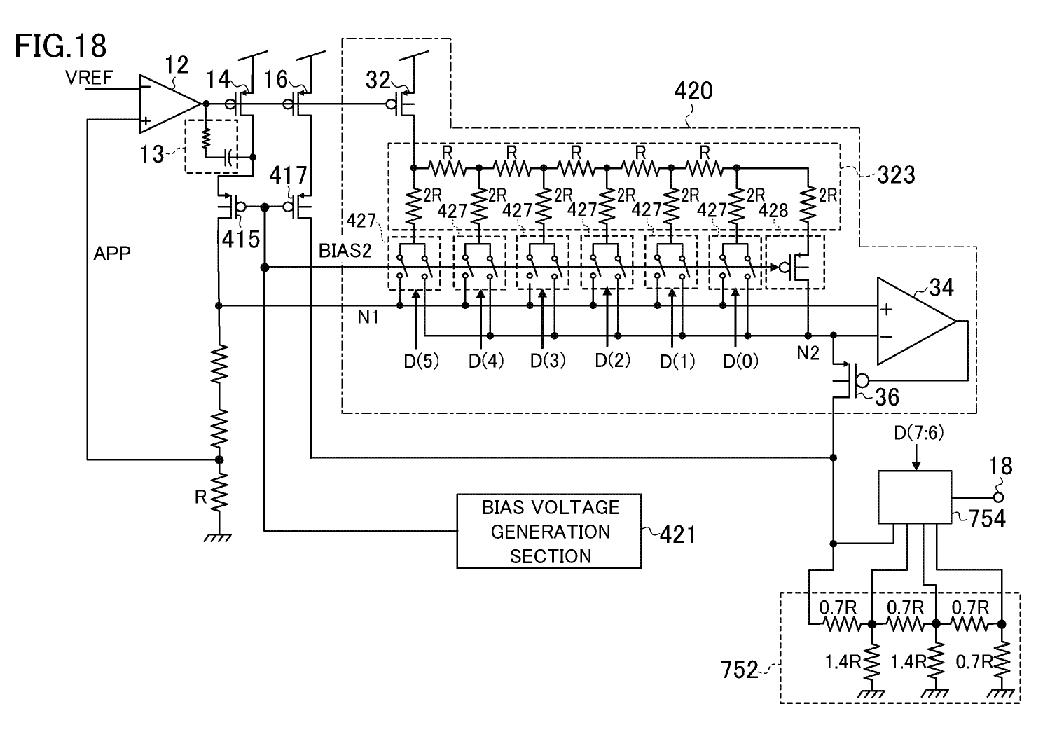

FIG. 18 is a circuit diagram illustrating a configuration of a second variation of the voltage control circuit of FIG. 16. The voltage control circuit of FIG. 18 differs from that of FIG. 17 in that the former includes an R-2R resistor ladder 752, as a load resistor circuit, and a selector 754 instead of the load resistor 652, and a resistor instead of the reference-current control section 40. The selector 754 selects a tap of the resistor ladder 752 according to higher bits D(7:6) of the gain control signal D, and outputs the voltage of the selected tap to the output terminal 18.

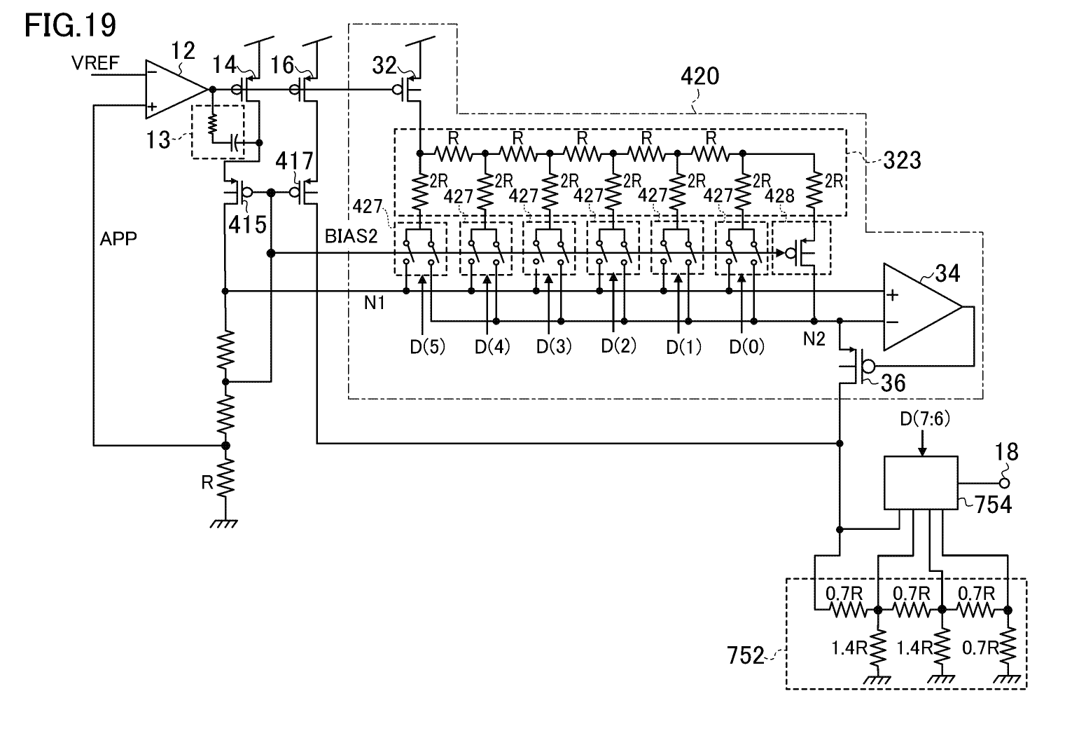

FIG. 19 is a circuit diagram illustrating a configuration of a third variation of the voltage control circuit of FIG. 16. The voltage control circuit of FIG. 19 differs from that of FIG. 18 in that the former does not include the bias voltage generation section 421, and that a voltage divided from the voltage of the drain of the PMOS transistor 415 is used as the bias voltage BIAS2. The configuration of the circuit of FIG. 19 can simplify the circuit.

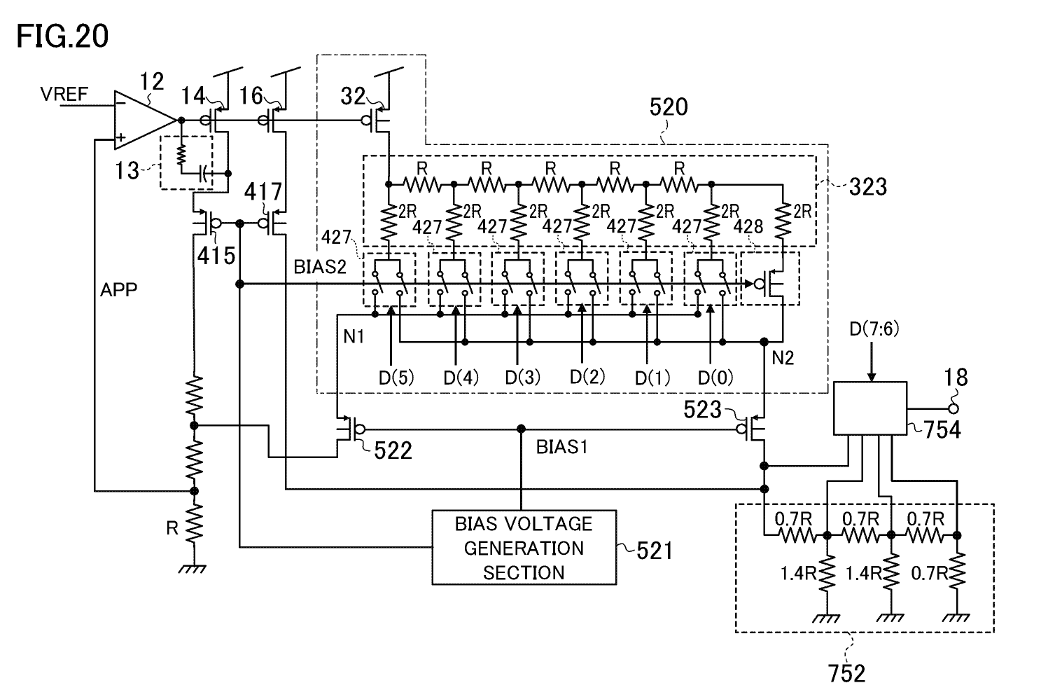

FIG. 20 is a circuit diagram illustrating a configuration of a fourth variation of the voltage control circuit of FIG. 16. The voltage control circuit of FIG. 20 differs from that of FIG. 17 in that the former includes a variable-current control section 520 and a bias voltage generation section 521 instead of the variable-current control section 420 and the bias voltage generation section 421, and further includes PMOS transistors 522 and 523. The variable-current control section 520 differs from the variable-current control section 420 in that the former does not include either the operational amplifier 34 or the PMOS transistor 36.

The voltage control circuit of FIG. 20 has a main part configured almost the same as that of the current control circuit of FIG. 11; therefore, a detailed explanation of the voltage control circuit of FIG. 20 will be omitted. Since the voltage control circuit of FIG. 20 does not include the operational amplifier 34, circuit operations can be stabilized.

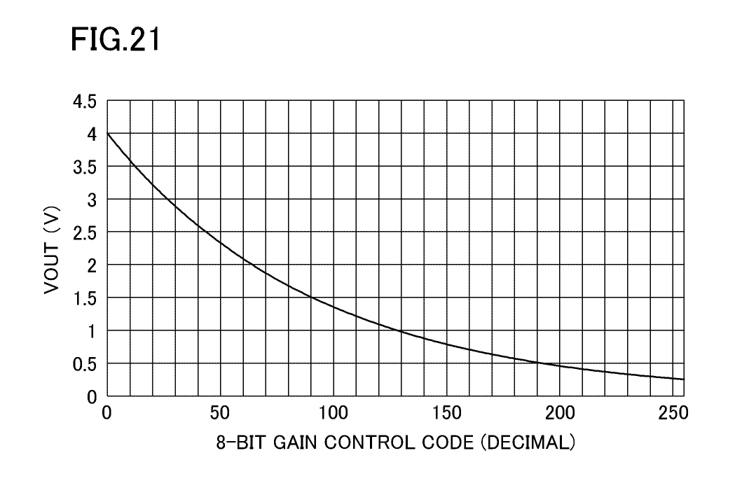

FIG. 21 is a graph showing an output voltage characteristic of the voltage control circuit 600 of FIG. 16. FIG. 21 shows a relationship between the gain control code, which is the value of the gain control signal D, and the output voltage VOUT (this is a case of 0 dB at 1 V and when the gain control code is 128). It is shown that the output voltage VOUT exponentially decreases with the gain control code.

Note that, in the voltage control circuit of FIG. 16, any of the variable-current control sections of FIGS. 5-7 may be used.

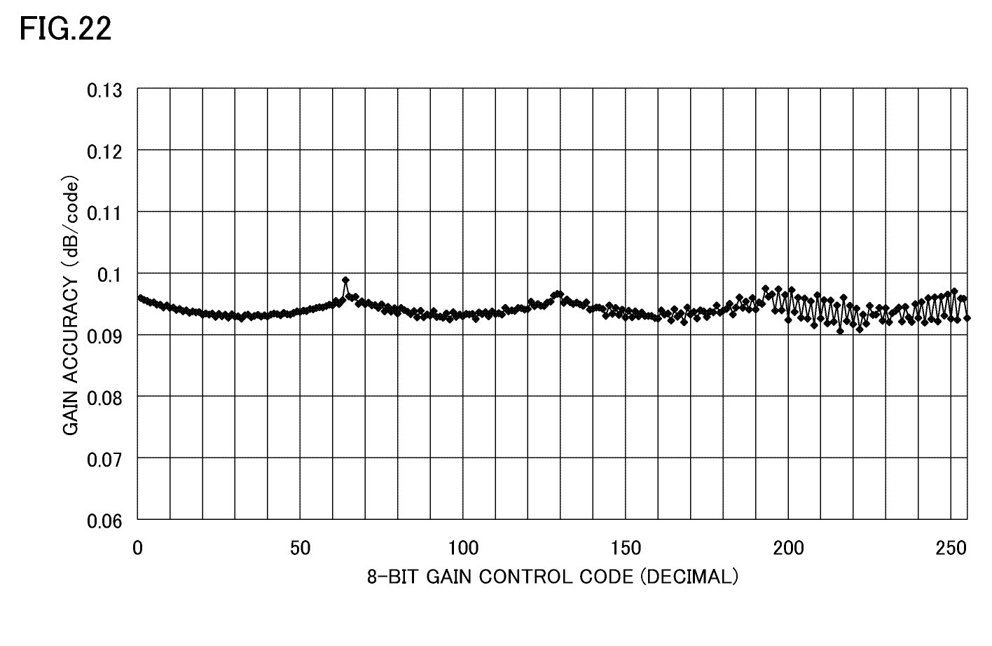

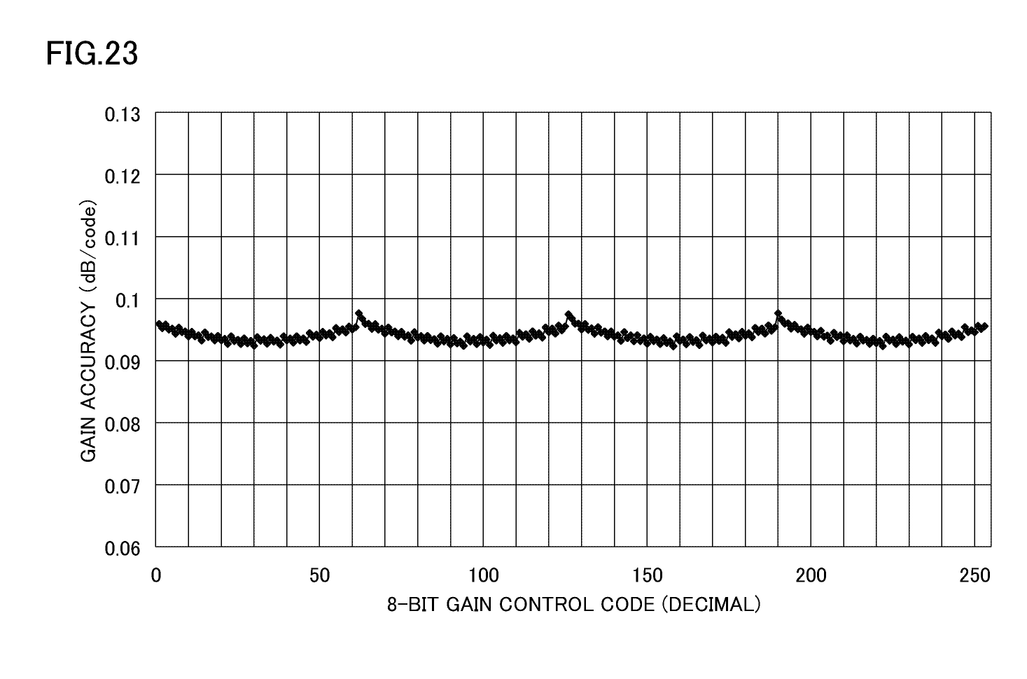

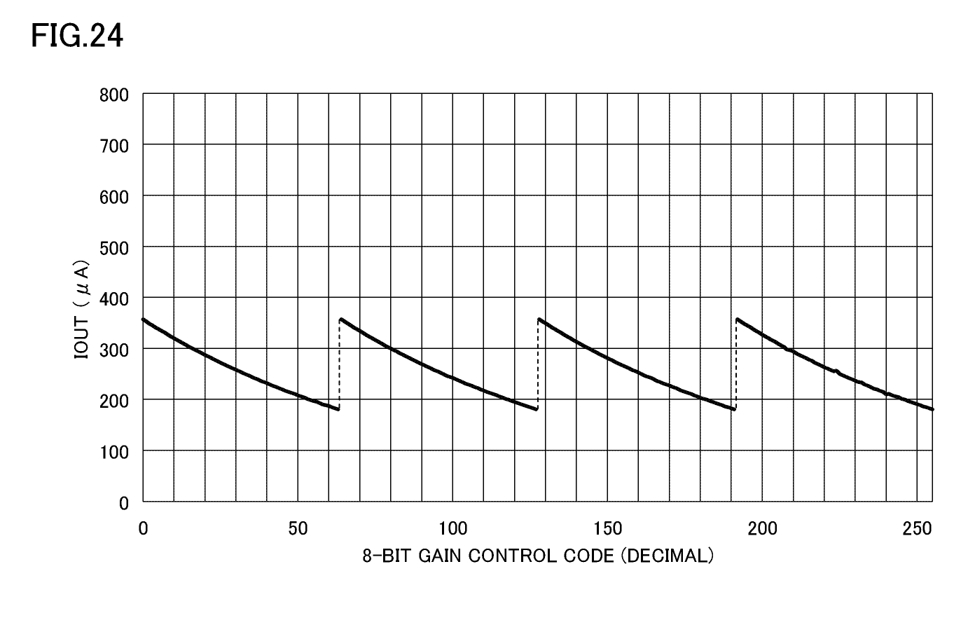

FIG. 22 is a graph showing gain accuracy of the single-slope ADCs of FIGS. 15A and 15B when the voltage control circuit of FIG. 17 is used. FIG. 23 is a graph showing gain accuracy of the single-slope ADCs of FIGS. 15A and 15B when the voltage control circuit of FIG. 20 is used. FIG. 24 is a graph showing an output current of the voltage control circuit of FIG. 20.

In the case of FIG. 22, the output current which flows through the load resistor varies over the entire range of the control code as shown in FIG. 12, thereby causing the current of each current source to be reduced particularly in a high-gain region. Since current accuracy relative to the flowed current is reduced, the gain control accuracy slightly varies. On the contrary, in the case of FIG. 23, a current variation pattern is repeated within the control range by the lower bits of the gain control signal D, and current flows through each current source to some degree over the entire range as shown in FIG. 24. This ensures almost constant control accuracy. Note that the variation of gain accuracy is less than or equal to 0.01 dB in either case, thereby allowing high accuracy of gain control to be provided.

A case will be described where, in the voltage control circuits of FIGS. 18-20, the output voltage corresponding to a gain of 0 dB is set to the reference potential VREF. Let R be the resistance value of the resistor which generates the reference current. Then, using a calculation similar to that applied to Equations 8 and 9 described above, the value of the resistance to ground of the selected tap of the resistor ladder 752 should be 0.7R. Assuming that n=8 and the value of the gain control signal D (8-bit control code value) when 0 dB is set is, for example, 80h (hexadecimal), the most-significant two bits of the gain control signal D are (1, 0). Since the value of the resistance to ground of the tap selected by the selector 754 should be 0.7 R, the R-2R resistor ladder 752 should be configured with resistors each having a resistance value of 1.4R and resistors each having a resistance value of 0.7R as shown in FIGS. 18-20. The gain characteristic of a single-slop ADC using either of the voltage control circuits of FIGS. 18-20 is, similarly to a case where a current control circuit is used, as shown in FIG. 13.

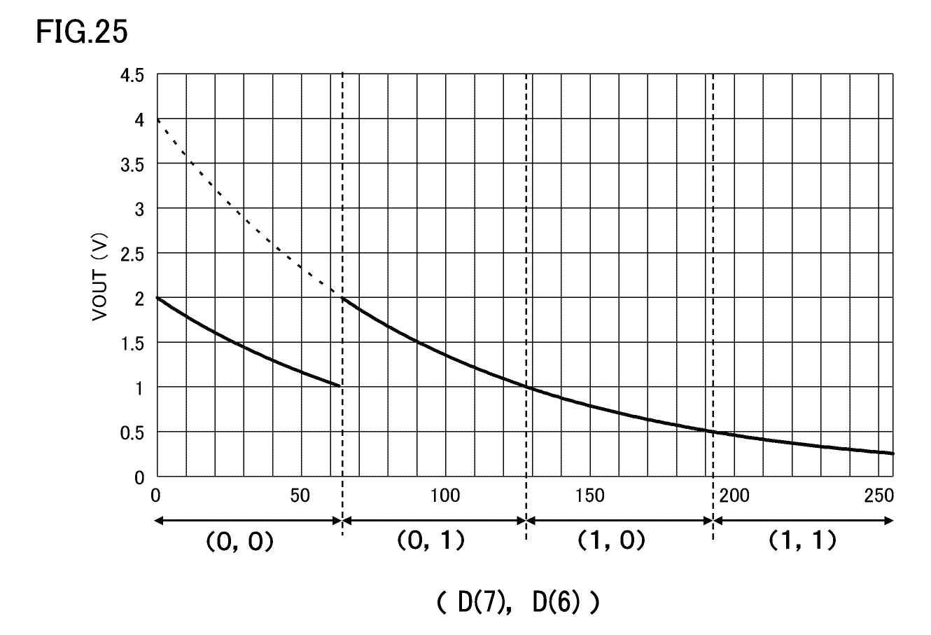

FIG. 25 is a graph showing an example of an output voltage characteristic of a voltage control circuit. For example, when VREF=1 V, the voltage control circuits of FIGS. 16-20 generate the output voltage VOUT of 4V at −12 dB as shown in FIG. 21. The supply voltage of an image sensor is about 3 V in general; therefore, the output voltage VOUT exceeds the supply voltage. Thus, if the single-slop ADC is directly incorporated into an image sensor, then a broader dynamic range cannot be obtained.

Accordingly, the outputs of the voltage control circuits of FIGS. 16-20 are each controlled to have a characteristic as shown in FIG. 25. That is, when the gain range is from −12 dB to −6 dB (i.e., the gain control code is 0-63, thus the most-significant two bits of the gain control signal D are (0, 0)), each of the voltage control circuits of FIGS. 16-20 controls the output voltage VOUT so that the output voltage VOUT is one half of a usual value; in other words, control of the output voltage VOUT is provided similarly to the case where the gain range is from −6 dB to 0 dB (i.e., the gain control code is 64-127, thus the most-significant two bits of the gain control signal D are (0, 1)). In this case, the drive frequency of the DAC 602 is doubled so that the DAC 602 changes the reference ramp signal SLS at a rate twice a usual rate. That is, the time required for the reference ramp signal SLS to reach the output voltage VOUT is reduced by half. This allows the slope of the reference ramp signal SLS to be the same as that when the output voltage VOUT is the voltage shown by the broken line in FIG. 25, thereby allows the gain to be variable until −12 dB.

Note that the configuration may be such that the output voltage VOUT is 1/k of a usual value (where k is a positive real number), and at the same time, the reference ramp signal SLS is changed at a rate k times a usual rate.

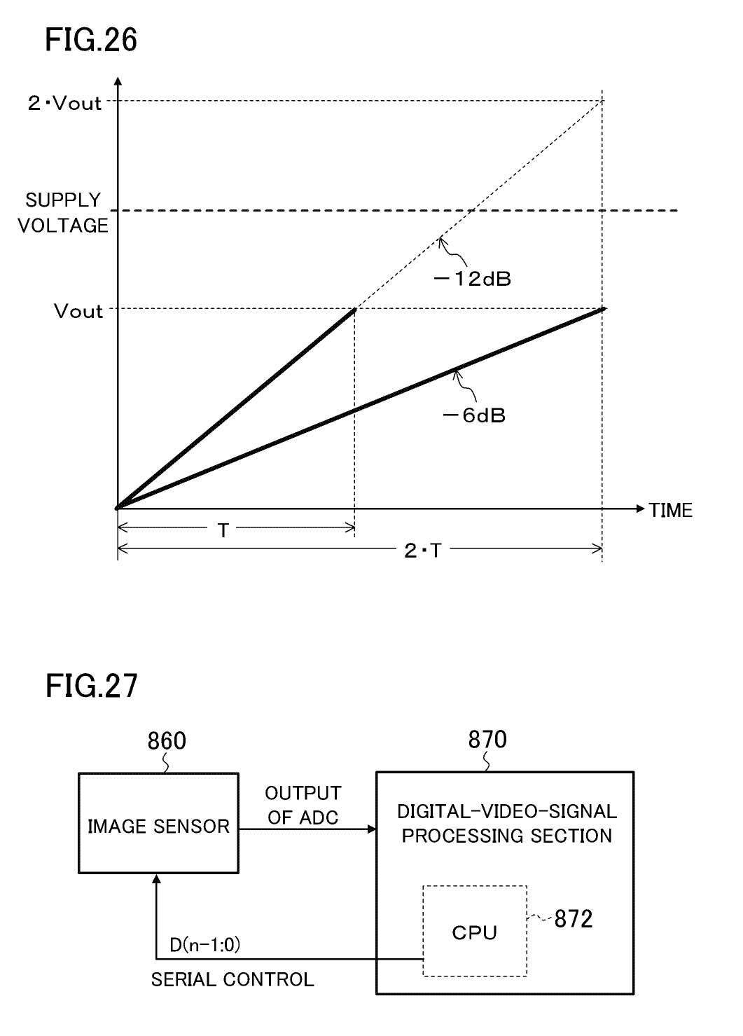

FIG. 26 is an illustrative diagram of the slope of the reference ramp signal SLS. Such control can be provided by supplying the control signal DCN so that, for example, the counter 8 counts up twice as fast in the single-slope ADC of FIG. 15B when the most-significant two bits of the gain control signal D are (0, 0).

FIG. 27 is a block diagram illustrating an example configuration of a camera which uses an image sensor including a single-slope ADC having a variable-gain function. The camera of FIG. 27 includes an image sensor 860 and a digital-video-signal processing section 870. The digital-video-signal processing section 870 includes a CPU 872.

An output signal from an ADC in the image sensor 860 is input to the digital-video-signal processing section 870. The digital-video-signal processing section 870 calculates the average value of the ADC output signal level every frame period, and determines whether or not the amplitude of an output signal from photodiodes which varies depending on the amount of incident light to the image sensor 860 is in an optimum state for the input range of the ADC, by comparing the average value with a predetermined reference value. The digital-video-signal processing section 870 increases the value of the gain control signal D(n−1:0) to amplify the output signal of the image sensor 860 when the output signal is low, while, on the contrary, the digital-video-signal processing section 870 decreases the value of the gain control signal D(n−1:0) to attenuate the output signal when the output signal is high and near saturation. The digital-video-signal processing section 870 outputs the gain control signal D(n−1:0) to the image sensor 860, for example, using serial communication.

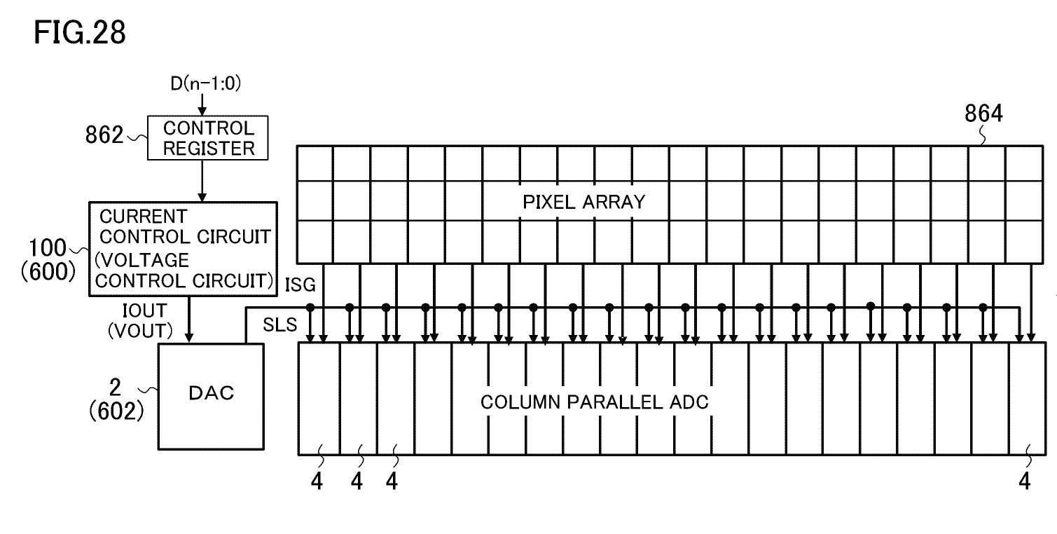

FIG. 28 is a block diagram illustrating an example configuration of the image sensor 860 of FIG. 27. The image sensor 860 includes a control register 862, a current control circuit 100, a DAC 2, a plurality of column parallel ADCs 4, and a pixel array 864. Although not shown in FIG. 28, the DAC 2 receives a counter value from one of the column parallel ADCs 4 or a counter 8 as shown in FIGS. 1A and 1B.

The control register 862 stores and outputs the gain control signal D(n−1:0) to the current control circuit 100. The current control circuit 100 and the DAC 2 have already been described, thus the explanation thereof will be omitted. The pixel array 864 includes a plurality of photodiodes, for example, arranged in a matrix, and outputs an output signal from the photodiodes for every column of photodiodes as a signal ISG. Each of the plurality of column parallel ADCs 4 corresponds to a column of photodiodes, and obtains and outputs an analog-to-digital conversion result ADV of the signal ISG from a corresponding column of photodiodes, using the common reference ramp signal SLS output from the DAC 2.

In FIG. 28, the current control circuit 100 may be implemented by any of the current control circuits described above. Moreover, a voltage control circuit 600 and a DAC 602 may be used instead of the current control circuit 100 and the DAC 2. The voltage control circuit 600 may be implemented by any of the voltage control circuits described above.

Human visual perception of brightness is said to have characteristics such that sensitivity to low brightness is high, while sensitivity to high brightness is low. As such, gains are generally controlled so that the smaller the amplitude of a video signal is, the higher the resolution of an ADC is. That is, an optimum gain control is one in which the gain is increased for a low-amplitude signal, and the gain has a nonlinear exponential characteristic for the value of a control signal.

Conventionally, such nonlinear characteristic has been achieved by previously performing nonlinearization using digital signal processing of the gain control signal itself, and by using the result thereof for the control to set the amplitude of the reference ramp signal in a DAC which generates the reference ramp signal. In the image sensor according to this embodiment, the logarithm of the current IOUT (or the voltage VOUT), referenced by the DAC 2 (or the DAC 602) which outputs the reference ramp signal SLS, is controlled so as to be proportional to the gain control signal D(n−1:0); therefore, the gain control signal D(n−1:0) needs no nonlinearization processing.

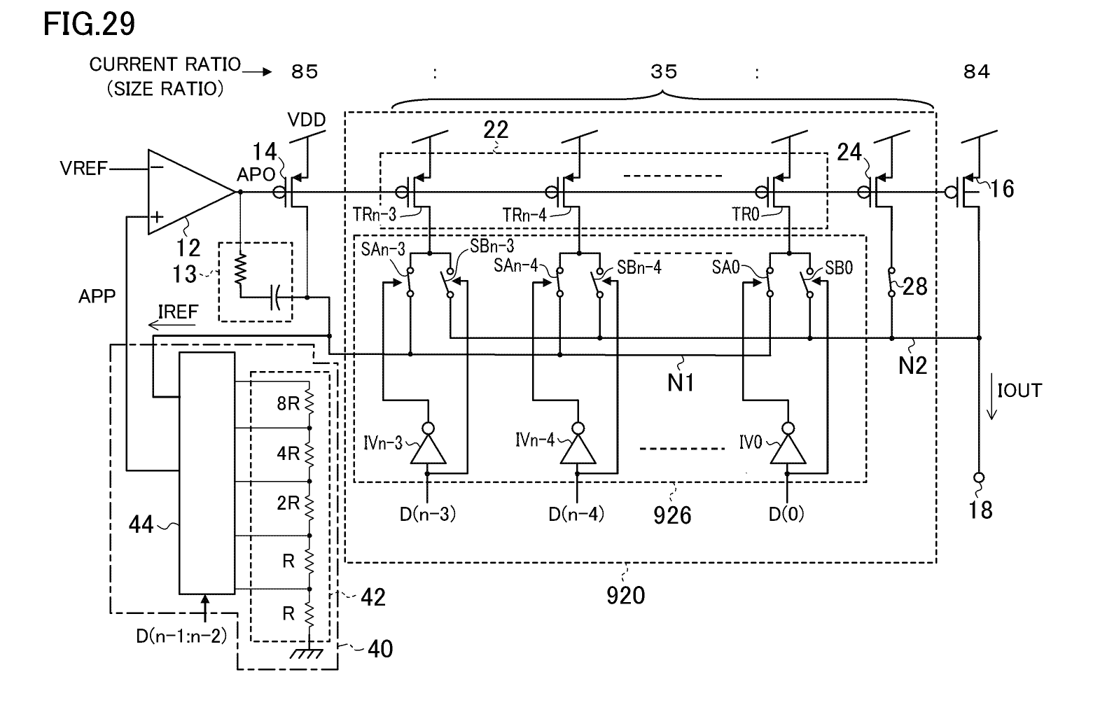

FIG. 29 is a circuit diagram illustrating a configuration of a variation of the current control circuit of FIG. 3, in which the output current increases as the value of the gain control signal D increases. Although the above embodiments are intended for cases where an increase of the value of the gain control signal D causes the output signal of the current control circuit (or the voltage control circuit) to be decreased (i.e., 2^{-x} is approximated), a reverse characteristic can be implemented, and in such a case, Equation 4 can be directly applied.

The current control circuit of FIG. 29 differs from that of FIG. 1 in that the former includes a variable-current control section 920 instead of the variable-current control section 20. The variable-current control section 920 includes a current switching section 926. A circuit configuration corresponding to the denominator in Equation 4 should be provided in the circuit to generate the reference current, and a circuit configuration corresponding to the numerator should be provided in the output side. Thus, in FIG. 29, the ratio between the current of the PMOS transistor 14 (first current output section), the current of the PMOS transistor 16 (second current output section), and the sum of the currents of the current source set 22 and the unit current source 24 of the variable-current control section 920 is set to approximately 85:84:35. Inverted signals with respect to those of FIG. 3 are provided to the respective switches of the current switching section 926 of the variable-current control section 920.

The characteristic expressed by Equation 4 can be achieved also in the current control circuits and the voltage control circuits of figures other than FIG. 3 in a similar way. Since the configurations are obvious, the description thereof will be omitted.

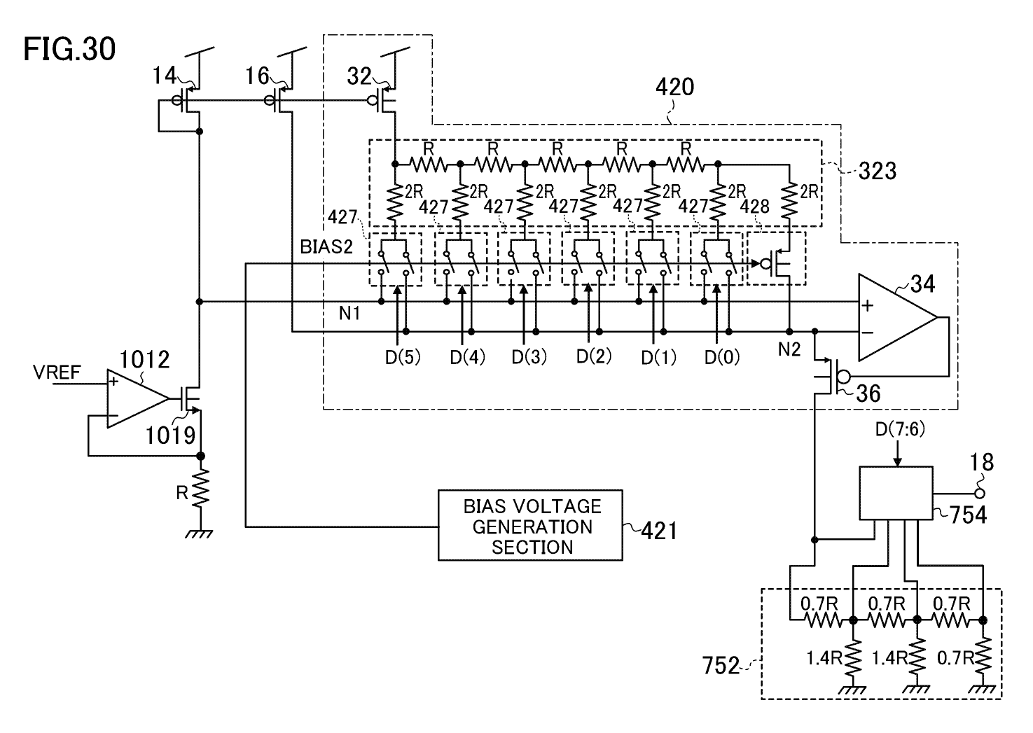

FIG. 30 is a circuit diagram illustrating a configuration of a variation of the voltage control circuit of FIG. 18. The voltage control circuit of FIG. 30 differs from that of FIG. 18 in that the former includes an operational amplifier 1012 and an NMOS transistor 1019 instead of the operational amplifier 12, the phase compensation circuit 13, and the PMOS transistors 415, 417, etc. The PMOS transistors 14, 16, and 32 form a current mirror, and the operational amplifier 1012 provides control so that the sum of the current of the PMOS transistor 14 and the current flowing from the variable-current control section 420 to the node N1 is maintained at a constant value. The voltage control circuit of FIG. 30 can simplify the circuit. Also in the current control circuits and the other voltage control circuits described above, the control of the PMOS transistor 14 and the current paths of the PMOS transistors 14 and 16 may be similar to those of the voltage control circuit of FIG. 30.

Although the description in association with FIGS. 18-20 has been presented for cases where an R-2R resistor ladder is used as a load resistor, other resistors may be used. That is, any configuration may be used as long as each potential of voltage division taps selected by higher bits of the gain control signal D is a potential corresponding to the weights of respective bits.

Whereas each of the above current control circuits and the above voltage control circuits uses PMOS transistors, NMOS transistors may be used instead of PMOS transistors. In such a case, the PMOS transistors should be replaced with NMOS transistors, and ground and the power source should be exchanged in each of the current control circuits and the voltage control circuits. Such a configuration can generate, for example, a reference ramp signal having a value decreasing with time. In addition, the power supply potential and/or ground may be other stable potentials.

Note that the R-2R resistor ladder 323 of FIGS. 7, 8, 10, 11, and 17-20, and the R-2R resistor ladder 752 of FIGS. 18-20 are presented merely by way of example, thus the number of the resistors and the number of the taps included in these resistor ladders may be more or less than the numbers illustrated in the examples.

In the described embodiments, the resistance values of the resistor chain 42, the load resistor 652, and R-2R resistor ladders 323 and 752 are presented merely by way of example, thus may be other values as long as the values have a predetermined relationship. The number of bits of the lower bits (first control signal) of the gain control signal D and the number of bits of the higher bits (second control signal) of the gain control signal D are presented merely by way of example, thus may be other numbers.

Although the foregoing description discusses examples in which the DAC 2 and the DAC 602 generate a reference ramp signal SLS having a voltage which increases proportionally to the count value of the counter 6 or 8, the voltage of the reference ramp signal SLS may decrease as the count value of the counter 6 or 8 increases. For example, the DAC 2 or the DAC 602 may generate a reference ramp signal SLS having a voltage which decreases proportionally to the count value of the counter 6 or 8 from the maximum value.

The many features and advantages of the invention are apparent from the detailed specification and, thus, it is intended by the appended claims to cover all such features and advantages of the invention which fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

As has been described above, according to the present invention, a linear relationship is established between the gain control signal and the amplification factor (value in dB), thus the present invention is useful for current generation circuits, ADCs, cameras, etc.

What is claimed is:

1. A current generation circuit, comprising:
a first current output section configured to output a first current;
a second current output section configured to output a second current proportional to the first current; and
a variable-current control section configured to generate a third current proportional to the first current, to divide the third current into a fourth current and a fifth current according to a first control signal, and to output the fourth and the fifth currents,
wherein
the current generation circuit outputs a sum of the first and the fourth currents as a reference current, and a sum of the second and the fifth currents as an output current.

2. The current generation circuit of claim 1, further comprising:
a resistor circuit configured to supply the reference current to a reference potential node; and
an operational amplifier having an inverting input supplied with a reference potential and a non-inverting input supplied with a potential in the resistor circuit,
wherein
an output signal of the operational amplifier is supplied to the first and the second current output sections and to the variable-current control section, as a bias signal.

3. The current generation circuit of claim 2, further comprising:
a selector,
wherein
the resistor circuit includes a plurality of resistors connected in series;
a resistance value between one of a plurality of taps which are connection points between the plurality of resistors and the reference potential node is a power-of-two times as high as a resistance value between another one of the plurality of taps and the reference potential node; and
the selector selects one of the plurality of taps according to a second control signal, and connects the selected tap to the non-inverting input of the operational amplifier.

4. The current generation circuit of claim 1, further comprising:
a load resistor circuit configured to supply the output current to a reference potential node.

5. The current generation circuit of claim 4, further comprising:
a selector,
wherein
the load resistor circuit includes an R-2R resistor ladder, and
the selector selects a tap of the R-2R resistor ladder according to a second control signal, and outputs a potential of the selected tap.

6. The current generation circuit of claim 1, wherein
a ratio between the magnitudes of the first current, the second current, and the third current is 84:85:35 or 85:84:35.

7. The current generation circuit of claim 1, wherein
the variable-current control section includes a plurality of current sources, each of which corresponds to each bit of the first control signal and outputs a current having a magnitude proportional to a number represented by a corresponding bit, and
the variable-current control section outputs each current of the plurality of current sources as the fourth or the fifth current according to the value of a corresponding bit of the first control signal.

8. The current generation circuit of claim 7, wherein
each of the plurality of current sources includes
a current source configured to generate a part of the fourth current, and
a current source configured to generate a part of the fifth current; and
the current source configured to generate a part of the fourth current and the current source configured to generate a part of the fifth current complementarily turn on according to the value of a corresponding bit of the first control signal.

9. The current generation circuit of claim 1, wherein
the variable-current control section includes
a third current output section configured to output the third current, and also includes, corresponding to each bit of the first control signal,
a first switch, connected to the third current output section, and configured to output a part of the third current as a part of the fourth current, and
a second switch, connected to the third current output section, and configured to output a part of the third current as a part of the fifth current;
resistance values of the first and the second switches are proportional to the reciprocal of a number represented by a corresponding bit of the first control signal; and
the first and the second switches complementarily turn on according to the value of a corresponding bit of the first control signal.

10. The current generation circuit of claim 1, wherein
the variable-current control section includes
a third current output section configured to output the third current, and
an R-2R resistor ladder, and also includes, corresponding to each bit of the first control signal,
a first switch, connected to an output terminal of the R-2R resistor ladder, and configured to output a part of the third current as a part of the fourth current, and
a second switch, connected to the output terminal of the R-2R resistor ladder, and configured to output a part of the third current as a part of the fifth current; and
the first and the second switches complementarily turn on according to the value of a corresponding bit of the first control signal.

11. The current generation circuit of claim 1, wherein
the variable-current control section further includes
a bias control circuit configured to control so that a potential of a first node into which the fourth current flows and a potential of a second node into which the fifth current flows are maintained at equal values.

12. The current generation circuit of claim 11, wherein
the bias control circuit includes
an operational amplifier having a non-inverting input connected to the first node, and an inverting input connected to the second node, and
a metal oxide semiconductor (MOS) transistor whose gate is coupled to the output of the operational amplifier and whose source is coupled to the second node.

13. The current generation circuit of claim 1, further comprising:
a bias voltage generation section configured to generate a first and a second bias voltages;
a first bias MOS transistor whose source is coupled to the first current output section, and whose gate is supplied with the second bias voltage;
a second bias MOS transistor whose source is coupled to the second current output section, and whose gate is supplied with the second bias voltage;
a third bias MOS transistor whose gate is supplied with the first bias voltage, and through which the fourth current flows; and
a fourth bias MOS transistor whose gate is supplied with the first bias voltage, and through which the fifth current flows.

14. The current generation circuit of claim 1, wherein
the first and the second current output sections are both MOS transistors;
the variable-current control section includes a MOS transistor which outputs at least a part of the third current; and
a common bias signal is supplied to the MOS transistors, serving as the first or the second current output sections, and the MOS transistor of the variable-current control section.

15. A single-slope analog-to-digital converter (ADC), comprising:
a current generation circuit;
a digital-to-analog converter (DAC) configured to generate a reference ramp signal having a voltage which increases or decreases proportionally to an input count value; and
an ADC configured to output the count value,
wherein
the current generation circuit includes
a first current output section configured to output a first current,
a second current output section configured to output a second current proportional to the first current, and
a variable-current control section configured to generate a third current proportional to the first current, to divide the third current into a fourth current and a fifth current according to a first control signal, and to output the fourth and the fifth currents;
the current generation circuit outputs a sum of the first and the fourth currents as a reference current, and a sum of the second and the fifth currents as an output current;
a maximum value of the voltage of the reference ramp signal depends on the output current; and
the ADC counts up according to a clock signal, and outputs as a result of analog-to-digital conversion the count value when the reference ramp signal reaches the voltage of a signal to be converted.

16. A single-slope ADC, comprising:
a current generation circuit;
a DAC configured to generate a reference ramp signal having a voltage which increases or decreases proportionally to an input count value; and
an ADC configured to output the count value,
wherein
the current generation circuit includes
a first current output section configured to output a first current,
a second current output section configured to output a second current proportional to the first current,
a variable-current control section configured to generate a third current proportional to the first current, to divide the third current into a fourth current and a fifth current according to a first control signal, and to output the fourth and the fifth currents, and
a load resistor circuit;
the current generation circuit outputs a sum of the first and the fourth currents as a reference current, and a sum of the second and the fifth currents as an output current;
the load resistor circuit supplies the output current to a reference potential node;
a maximum value of the voltage of the reference ramp signal depends on an output voltage generated in the load resistor circuit; and
the ADC counts up according to a clock signal, and outputs as a result of analog-to-digital conversion the count value when the reference ramp signal reaches the voltage of a signal to be converted.

17. The single-slope ADC of claim 16, wherein
the current generation circuit reduces the output voltage to 1/k (where k is a positive real number) if a second control signal is a predetermined value, and
the DAC changes the reference ramp signal at a rate k times a usual rate.

18. A camera, comprising:
an image sensor configured to convert light which is input to each pixel into a voltage and to output the voltage; and
a digital-video-signal processing section configured to perform signal processing on an output of the image sensor,
wherein
the image sensor includes
a pixel array, having a plurality of photodiodes corresponding to the respective pixels, and configured to output an electrical signal depending on detected light, for each column of the plurality of photodiodes,
a current generation circuit,
a DAC configured to generate a reference ramp signal having a voltage which increases or decreases proportionally to an input count value, and
a plurality of column parallel ADCs respectively corresponding to the columns of the plurality of photodiodes;
the current generation circuit includes
a first current output section configured to output a first current,
a second current output section configured to output a second current proportional to the first current, and
a variable-current control section configured to generate a third current proportional to the first current, to divide the third current into a fourth current and a fifth current according to a first control signal, and to output the fourth and the fifth currents;
the current generation circuit outputs a sum of the first and the fourth currents as a reference current, and a sum of the second and the fifth currents as an output current;
a maximum value of the voltage of the reference ramp signal depends on the output current; and
the plurality of column parallel ADCs each counts up according to a clock signal, and each outputs as a result of analog-to-digital conversion the count value when the reference ramp signal reaches the voltage of a signal output from a corresponding column of the plurality of photodiodes.
